(19) United States
(12) Patent Application Publication
(10) Pub. No.: US 2024/0324376 A1
(43) Pub. Date: Sep. 26, 2024

(54) DISPLAY PANEL AND ELECTRONIC APPARATUS INCLUDING THE SAME

(71) Applicant: Samsung Display Co., Ltd., Yongin-si (KR)

(72) Inventor: Junhyun Park, Yongin-si (KR)

(21) Appl. No.: 18/614,528

(22) Filed: Mar. 22, 2024

(30) Foreign Application Priority Data
Mar. 24, 2023 (KR) 10-2023-0039117
Oct. 11, 2023 (KR) 10-2023-0135447

(51) Int. Cl. H10K 59/131; H10K 59/121

(52) U.S. Cl. CPC H10K 59/1315; H10K 59/1213; H10K 59/1216

(57) ABSTRACT

A display panel includes: a substrate including: a transmission area; and a display area; a first pixel circuit at the display area; a second pixel circuit at a same row as that of the first pixel circuit, and spaced from the first pixel circuit in a first direction with the transmission area therebetween; a first horizontal conductive line spaced from the transmission area in a second direction; a second horizontal conductive line including: a first portion overlapping the first pixel circuit; and a second portion spaced from the first portion with the transmission area therebetween, and overlapping the second pixel circuit; a first vertical conductive line overlapping the first pixel circuit, and electrically connected to the first horizontal conductive line and the first portion; and a second vertical conductive line overlapping the second pixel circuit, and electrically connected to the first horizontal conductive line and the second portion.

### CROSS-REFERENCE TO RELATED APPLICATIONS

The present application claims priority to and the benefit of Korean Patent Application Nos. 10-2023-0039117, filed on Mar. 24, 2023, and 10-2023-0135447, filed on Oct. 11, 2023, in the Korean Intellectual Property Office, the entire disclosures of all of which are incorporated by reference herein.

### BACKGROUND

### 1. Field

One or more embodiments of the present disclosure relate to a display panel, and an electronic apparatus including the display panel.

### 2. Description of the Related Art

Recently, the usage of display devices has diversified. In addition, as the use of display devices has expanded, a demand for high-resolution display devices has increased. To manufacture high-resolution display devices, various processes may be performed.

### SUMMARY

One or more embodiments of the present disclosure are directed to a display panel having improved display quality, and an electronic apparatus including the display panel. However, the aspects and features of the present disclosure are not limited thereto or thereby.

The above and additional aspects and features will be set forth, in part, in the description that follows, and in part, will be apparent from the description, or may be learned by practicing one or more of the presented embodiments of the present disclosure.

According to one or more embodiments of the present disclosure, a display panel includes: a substrate including: a transmission area; and a display area surrounding the transmission area; a plurality of pixel circuits in the display area, and including: a first pixel circuit; and a second pixel circuit at a same row as that of the first pixel circuit, and spaced from the first pixel circuit in a first direction with the transmission area therebetween; a first horizontal conductive line extending in the first direction, and spaced from the transmission area in a second direction crossing the first direction; a second horizontal conductive line including: a first portion extending in the first direction, and overlapping with the first pixel circuit; and a second portion extending in the first direction, spaced from the first portion with the transmission area therebetween, and overlapping with the second pixel circuit; a first vertical conductive line extending in the second direction, overlapping with the first pixel circuit, and electrically connected to the first horizontal conductive line and the first portion of the second horizontal conductive line; and a second vertical conductive line extending in the second direction, overlapping with the second pixel circuit, and electrically connected to the first horizontal conductive line and the second portion of the second horizontal conductive line.

In an embodiment, the first horizontal conductive line and the first vertical conductive line may be located at different layers from each other.

In an embodiment, the display panel may further include an insulating layer between the first horizontal conductive line and the first vertical conductive line. The first horizontal conductive line may be located below the insulating layer, and the first vertical conductive line may be located above the insulating layer.

In an embodiment, the plurality of pixel circuits may further include: a third pixel circuit at the same row as that of the first pixel circuit and the second pixel circuit; and a fourth pixel circuit at the same row as that of the first pixel circuit and the second pixel circuit, and spaced from the third pixel circuit in the first direction with the transmission area therebetween. The display panel may further include: a third horizontal conductive line extending in the first direction, and spaced from the transmission area in the second direction; a fourth horizontal conductive line including: a first portion extending in the first direction, and overlapping with the third pixel circuit; and a second portion spaced from the first portion of the fourth horizontal conductive line with the transmission area therebetween, extending in the first direction, and overlapping with the fourth pixel circuit; a third vertical conductive line extending in the second direction, overlapping with the third pixel circuit, and electrically connected to the third horizontal conductive line and the first portion of the fourth horizontal conductive line; and a fourth vertical conductive line extending in the second direction, overlapping with the fourth pixel circuit, and electrically connected to the third horizontal conductive line and the second portion of the fourth horizontal conductive line.

In an embodiment, the third vertical conductive line may not overlap with the first pixel circuit, and the fourth vertical conductive line may not overlap with the second pixel circuit.

In an embodiment, the second horizontal conductive line may be configured to transmit a bias voltage to the first to fourth pixel circuits, and the fourth horizontal conductive line may be configured to transmit an initialization voltage to the first to fourth pixel circuits.

In an embodiment, the third horizontal conductive line and the third vertical conductive line may be located at different layers from each other.

In an embodiment, the third vertical conductive line may be located at a same layer as that of the first vertical conductive line.

In an embodiment, the first portion of the second horizontal conductive line may overlap with the first vertical conductive line and the third vertical conductive line, may be electrically connected to the first vertical conductive line, and may be electrically isolated from the third vertical conductive line. The first portion of the fourth horizontal conductive line may overlap with the first vertical conductive line and the third vertical conductive line, may be electrically isolated from the first vertical conductive line, and may be electrically connected to the third vertical conductive line.

In an embodiment, the first vertical conductive line may include: a first protrusion overlapping with the first horizontal conductive line; and a second protrusion overlapping with the third horizontal conductive line. The first vertical conductive line may be electrically connected to the first horizontal conductive line through a contact hole located directly below the first protrusion of the first vertical conductive line, and a contact hole may not be located directly below the second protrusion of the first vertical conductive line.

In an embodiment, the third vertical conductive line may include: a first protrusion overlapping with the first horizontal conductive line; and a second protrusion overlapping with the third horizontal conductive line. The third vertical conductive line may be electrically connected to the third horizontal conductive line through a contact hole located directly below the second protrusion of the third vertical conductive line, and a contact hole may not be located directly below the first protrusion of the third vertical conductive line.

In an embodiment, the plurality of pixel circuits may further include a fifth pixel circuit between the first pixel circuit and the third pixel circuit, and the display panel may further include a common voltage line extending in the second direction, and overlapping with the fifth pixel circuit.

In an embodiment, the common voltage line may be located at a same layer as that of the first vertical conductive line and the third vertical conductive line.

In an embodiment, the common voltage line may overlap with the first portion of the second horizontal conductive line and the first portion of the fourth horizontal conductive line, and may be electrically isolated from the first portion of the second horizontal conductive line and the first portion of the fourth horizontal conductive line.

In an embodiment, the common voltage line may include: a first protrusion overlapping with the first horizontal conductive line; and a second protrusion overlapping with the third horizontal conductive line. A contact hole may not be located directly below the first protrusion and the second protrusion of the common voltage line.

In an embodiment, the display panel may further include an auxiliary voltage line surrounding the transmission area, and electrically connecting the first portion and the second portion of the second horizontal conductive line to each other.

In an embodiment, the second horizontal conductive line may further include a third portion extending in the first direction, and connecting the first portion and the second portion of the second horizontal conductive line to each other across the transmission area.

In an embodiment, the plurality of pixel circuits may further include: a sixth pixel circuit; and a seventh pixel circuit spaced from the sixth pixel circuit in the second direction with the transmission area therebetween. The display panel may further include a fifth vertical conductive line including: a first portion extending in the second direction, and overlapping with the sixth pixel circuit; and a second portion spaced from the first portion of the fifth vertical conductive line with the transmission area therebetween, extending in the second direction, and overlapping with the seventh pixel circuit.

According to one or more embodiments of the present disclosure, a display panel includes: a substrate including: a transmission area; and a display area surrounding the transmission area; an array of a plurality of pixel circuits in the display area in a matrix form along a first direction and a second direction crossing the first direction; horizontal conductive lines extending in the first direction, and located along the second direction; and vertical conductive lines extending in the second direction, and located along the first direction. A first horizontal conductive line configured to transmit a first voltage and a second horizontal conductive line configured to transmit a second voltage from among the horizontal conductive lines overlap with a first row of the array that is spaced from the transmission area in the second direction. A third horizontal conductive line configured to transmit the first voltage and a fourth horizontal conductive line configured to transmit the second voltage from among the horizontal conductive lines overlap with a second row of the array that overlaps with the transmission area, the third horizontal conductive line and the fourth horizontal conductive line each including: a first portion; and a second portion spaced from the first portion in the first direction with the transmission area therebetween. A first vertical conductive line from among the vertical conductive lines overlaps with a first column of the array, is spaced from the transmission area in the first direction, and is electrically connected to the first horizontal conductive line and the first portion of the third horizontal conductive line. A second vertical conductive line from among the vertical conductive lines overlaps with a second column of the array between the first column and the transmission area, and is electrically connected to the second horizontal conductive line and the first portion of the fourth horizontal conductive line. A third vertical conductive line from among the vertical conductive lines overlaps with a third column that is spaced from the first column with the transmission area therebetween, and is electrically connected to the first horizontal conductive line and the second portion of the third horizontal conductive line. A fourth vertical conductive line from among the vertical conductive lines overlaps with a fourth column that is spaced from the second column with the transmission area therebetween, and is electrically connected to the second horizontal conductive line and the second portion of the fourth horizontal conductive line.

According to one or more embodiments of the present disclosure, an electronic apparatus includes: a display panel including: a transmission area; and a display area surrounding the transmission area; and a component on a back surface of the display panel, and corresponding to the transmission area. The display panel further includes: a plurality of pixel circuits in the display area, and including: a first pixel circuit; and a second pixel circuit located in a same row as that of the first pixel circuit, and spaced from the first pixel circuit in a first direction with the transmission area therebetween; a first horizontal conductive line extending in the first direction, and spaced from the transmission area in a second direction crossing the first direction; a second horizontal conductive line including: a first portion extending in the first direction, and overlapping with the first pixel circuit; and a second portion spaced from the first portion with the transmission area therebetween, extending in the first direction, and overlapping with the second pixel circuit; a first vertical conductive line extending in the second direction, overlapping with the first pixel circuit, and electrically connected to the first horizontal conductive line and the first portion of the second horizontal conductive line; and a second vertical conductive line extending in the second direction, overlapping with the second pixel circuit, and electrically connected to the first horizontal conductive line and the second portion of the second horizontal conductive line.

### BRIEF DESCRIPTION OF DRAWINGS

The above and other aspects and features of the present disclosure will be more clearly understood from the following detailed description of the illustrative, non-limiting embodiments with reference to the accompanying drawings, in which:

FIGS. 1A and 1B are perspective views schematically illustrating an electronic apparatus, according to one or more embodiments;

FIGS. 2A and 2B are cross-sectional views of the electronic apparatus taken along the line I-I′ of FIG. 1A, according to one or more embodiments;

FIG. 3 is a plan view schematically illustrating a display panel, according to an embodiment;

FIG. 4 is an equivalent circuit diagram illustrating a sub-pixel on a display panel, according to an embodiment;

FIG. 5 is a plan view schematically illustrating pixel circuits and lines on a display panel, according to an embodiment;

FIG. 6 is a plan view illustrating a sub-pixel on a display panel, according to an embodiment;

FIG. 7 is a cross-sectional view of the display panel taken along the line II-II′ of FIG. 6;

FIGS. 8A-8E are plan views schematically illustrating pixel circuits that are adjacent to one another in FIG. 5, and horizontal and vertical conductive lines overlapping with the pixel circuits;

FIG. 9 is a plan view schematically illustrating pixel circuits and lines on a display panel, according to an embodiment; and

FIG. 10 is a plan view schematically illustrating pixel circuits and lines on a display panel, according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

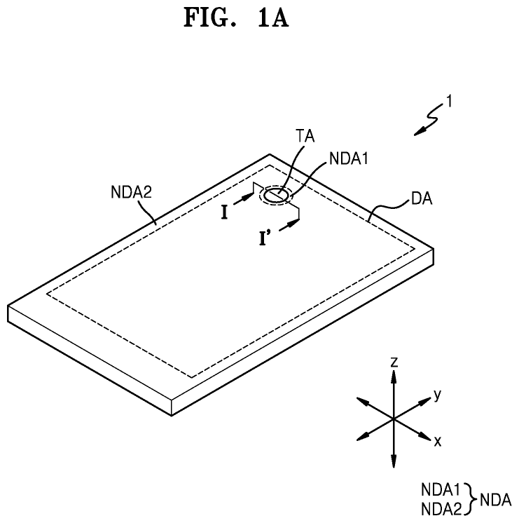

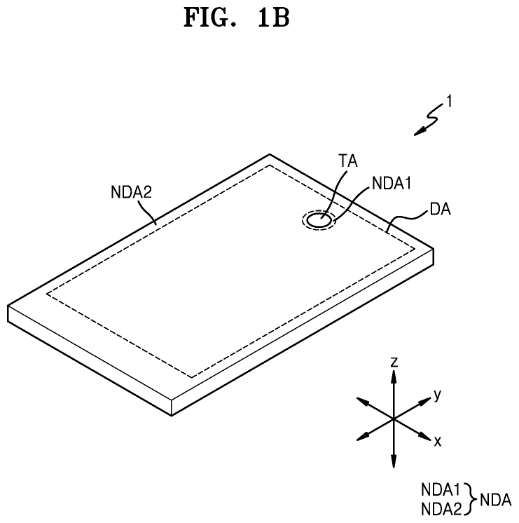

FIGS. 1A and 1B are perspective views schematically illustrating an electronic apparatus 1, according to one or more embodiments.

Referring to FIGS. 1A and 1B, the electronic apparatus 1 may display a moving image and/or a still image. The electronic apparatus 1 may be used as display screens of various suitable portable electronic apparatuses, such as mobile phones, smartphones, tablet personal computers (PCs), mobile communication terminals, electronic organizers, e-books, portable multimedia players (PMPs), navigation systems, and ultra mobile PCs (UMPCs). The electronic apparatus 1 may be used as display screens of various suitable products, such as televisions, laptops, monitors, billboards, and Internet of things (IoT) devices. The electronic apparatus 1 according to some embodiments may be used in various suitable wearable devices, such as smart watches, watch phones, glasses-type displays, and head mounted displays (HMDs). The electronic apparatus 1 according to some embodiments may be used in dashboards of automobiles, center information displays (CIDs) on the center fascia or the dashboards of automobiles, room mirror displays replacing side mirrors of automobiles, and displays on the rear sides of front seats to serve as entertainment devices for backseat passengers of automobiles. For convenience, the electronic apparatus 1 is illustrated and described in more detail hereinafter in the context of a smartphone as a representative example, but the present disclosure is not limited thereto.

In a plan view, the terms “left,” “right,” “up,” and “down” refer to corresponding directions when the electronic apparatus 1 is viewed from a vertical direction. For example, the term “left” refers to the −x direction, the term “right” refers to the +x direction, the term “up” refers to the +y direction, and the term “down” refers to the −y direction.

The electronic apparatus 1 may have a rectangular shape in a plan view. For example, as illustrated in FIGS. 1A and 1B, the electronic apparatus 1 may have a rectangular planar shape having a short side extending in the x direction, and a long side extending in the y direction. The corners at which the short sides extending in the x direction meet the long sides extending in the y direction may be rounded to have a suitable curvature (e.g., a certain or predetermined curvature), or may be at right angles. The planar shape of the electronic apparatus 1 is not limited to the rectangular shape, and may be in another polygonal shape, an elliptical shape, or an irregular shape.

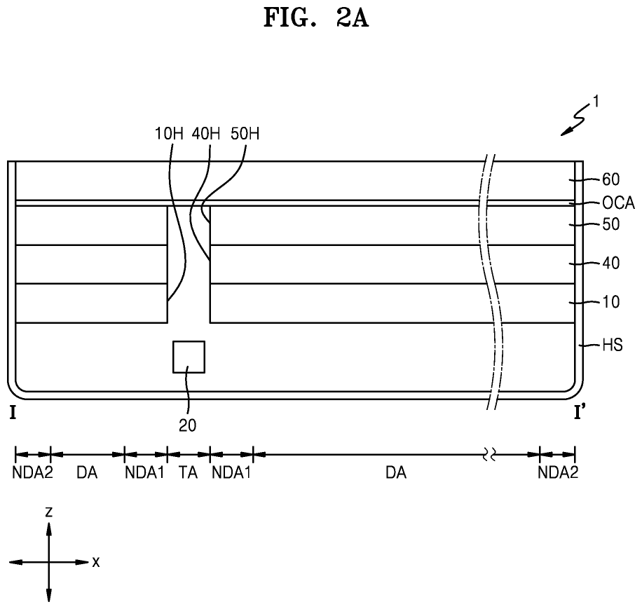

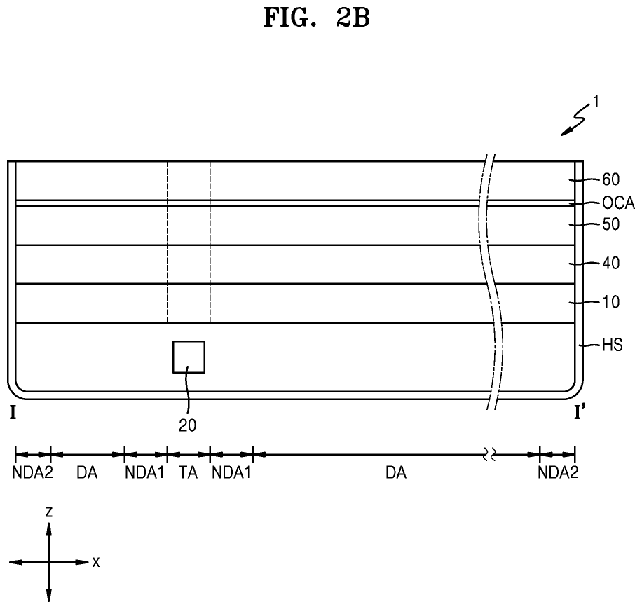

The electronic apparatus 1 may include at least one transmission area TA inside (e.g., within) a display area DA. FIGS. 1A and 1B illustrate one transmission area TA, but the present disclosure is not limited thereto, and the electronic apparatus 1 may include two or more transmission areas TA. The transmission area TA may be completely surrounded (e.g., around a periphery thereof) by the display area DA. The transmission area TA is an area in which one or more components described in more detail below with reference to FIGS. 2A and 2B may be arranged, and the electronic apparatus 1 may have various suitable functions using the one or more components.

Although FIG. 1A illustrates that the transmission area TA is arranged at the upper left side, the present disclosure is not limited thereto. In another embodiment, the transmission area TA may be arranged at the upper center, for example, as illustrated in FIG. 1B. In other embodiments, the transmission area TA may be arranged at various suitable positions. For example, the transmission area TA may be arranged at the upper right side of the display area DA, or at the center of the display area DA.

The display area DA may provide an image (e.g., a certain or predetermined image) by using light emitted from a plurality of sub-pixels that are arranged in the display area DA. The sub-pixels may each include a display element to emit light of a desired color (e.g., a certain or predetermined color). For example, display elements to emit red light, green light, and/or blue light may be two-dimensionally arranged along the x direction and the y direction, and may define the display area DA on which an image is displayed.

A non-display area NDA is an area in which the sub-pixels are not arranged. The non-display area NDA may include a first non-display area NDA1 surrounding (e.g., around a periphery of) the transmission area TA, and a second non-display area NDA2 surrounding (e.g., around a periphery of) the display area DA. The first non-display area NDA1 may be located between the transmission area TA and the display area DA, and the second non-display area NDA2 may be outside the display area DA.

FIGS. 2A and 2B are cross-sectional views of the electronic apparatus 1 taken along the line I-I′ of FIG. 1A, according to one or more embodiments. FIGS. 2A and 2B illustrate cross-sections taken along the line I-I′ of FIG. 1A, but a cross-sectional structure of FIG. 1B may have the same or substantially the same structure as that of any one of those described in more detail hereinafter with reference to FIGS. 2A and 2B.

Referring to FIGS. 2A and 2B, the electronic apparatus 1 may include a housing HS with one open side and having (e.g., defining) a space therein. The open side of the housing HS may be connected to (e.g., attached to or coupled to) a window 60.

A display panel 10, an input sensing layer 40, and an optical functional layer 50 may be disposed on a back surface of the window 60. A component 20 may be disposed on a back surface of the display panel 10.

The component 20 may be an electronic element that uses light or sound. Examples of the electronic element may include a sensor (e.g., a proximity sensor) to measure a distance, a sensor to recognize a part of a user's body (e.g., a fingerprint, an iris, a face, and/or the like), a small lamp to output light, or a camera. The electronic element that uses light may use light of various suitable wavelength bands, such as visible light, infrared light, and/or ultraviolet light. The electronic element that uses sound may use ultrasonic waves and/or sound of other suitable frequency bands.

The display panel 10 may display an image. The display panel 10 may display an image by using the display elements arranged in the display area DA. The display panel 10 may be a light-emitting display panel including a light-emitting diode. In an embodiment, the light-emitting diode may include an organic light-emitting diode including an organic emission layer. In another embodiment, the light-emitting diode may include an inorganic light-emitting diode including an inorganic material. The inorganic light-emitting diode may include a PN junction diode including one or more inorganic semiconductor-based materials. When a voltage is applied to the PN junction diode in a forward direction, holes and electrons may be injected and recombined with each other to generate energy, and the energy may be converted into light energy to emit light of a desired color (e.g., a certain or predetermined color). The inorganic light-emitting diode may have a width of several to hundreds of micrometers or several to hundreds of nanometers. In some embodiments, the inorganic light-emitting diode may be referred to as a micro light-emitting diode (e.g., a micro LED). The emission layer of the light-emitting diode may include the organic material or the inorganic material as described above, but the present disclosure is not limited thereto, and in another embodiment, the emission layer of the light-emitting diode may include quantum dots. In other words, the light-emitting diode may be a quantum dot light-emitting diode.

The display panel 10 may be a rigid display panel that may not be bent or may be hardly bent because of a high rigidity, or a flexible display panel that may be bendable, foldable, or rollable because of a high flexibility. For example, the display panel 10 may be a foldable display panel, a curved display panel with a curved display surface, a bent display panel in which areas other than a display surface are bent, a rollable display panel, or a stretchable display panel.

The input sensing layer 40 may obtain coordinate information according to an external input, for example, such as a touch event. The input sensing layer 40 may include a sensing electrode (e.g., a touch electrode), and trace lines connected to the sensing electrode. The input sensing layer 40 may be disposed on the display panel 10. The input sensing layer 40 may sense an external input by using a mutual capacitance method and/or a self-capacitance method.

The input sensing layer 40 may be formed directly on the display panel 10. For example, the input sensing layer 40 may be continuously formed after a process of forming the display panel 10. In this case, an adhesive layer may not be located between the input sensing layer 40 and the display panel 10. In another embodiment, the input sensing layer 40 may be formed separately from the display panel 10, and then connected to (e.g., attached to or coupled to) the display panel 10 through an adhesive layer. The adhesive layer may include an optical clear adhesive (OCA).

The optical functional layer 50 may include an anti-reflection layer. The anti-reflection layer may reduce a reflectance of light (e.g., external light) that may be incident from the outside toward the display panel 10 through the window 60. The anti-reflection layer may include a retarder and a polarizer.

In another embodiment, the anti-reflection layer may include a black matrix and color filters. The color filters may be arranged based on a color of the light emitted from each sub-pixel of the display panel 10. In another embodiment, the anti-reflection layer may include a destructive interference structure. The destructive interference structure may include a first reflective layer and a second reflective layer, which may be located at (e.g., in or on) different layers from each other. First reflected light and second reflected light reflected from the first reflective layer and the second reflective layer, respectively, may destructively interfere with each other, and thus, the reflectance of the external light may be reduced.

The optical functional layer 50 may include a lens layer. The lens layer may improve light output efficiency of the light emitted from the display panel 10, or may reduce a color shift. The lens layer may include a layer having a concave or convex lens shape, and/or may include a plurality of layers having different refractive indices from each other. The optical functional layer 50 may include either or both of the anti-reflection layer and the lens layer described above.

The optical functional layer 50 may be connected to (e.g., attached to or coupled to) the window 60 through an adhesive layer such as an OCA.

In some embodiments, the display panel 10, the input sensing layer 40, and/or the optical functional layer 50 may include through-holes, respectively, located in the transmission area TA. For example, as shown in FIG. 2A, the display panel 10, the input sensing layer 40, and the optical functional layer 50 may include a first through-hole 10H, a second through-hole 40H, and a third through-hole 50H, respectively. The first through-hole 10H may pass through (e.g., penetrate) the display panel 10 from the upper surface to the lower surface of the display panel 10. The second through-hole 40H may pass through (e.g., penetrate) the input sensing layer 40 from the upper surface to the lower surface of the input sensing layer 40. The third through-hole 50H may pass through (e.g., penetrate) the optical functional layer 50 from the upper surface to the lower surface of the optical functional layer 50.

In some embodiments, at least one selected from among the display panel 10, the input sensing layer 40, and/or the optical functional layer 50 may not include a through-hole. For example, one or two selected from among the display panel 10, the input sensing layer 40, and/or the optical functional layer 50 may not include a through-hole. However, the present disclosure is not limited thereto, and when it is possible to secure a transmittance of the transmission area TA, the display panel 10, the input sensing layer 40, and/or the optical functional layer 50 may not include a through-hole located in the transmission area TA, as illustrated in FIG. 2B. Further, in some embodiments, as shown in FIG. 2B, the first non-display area NDA1 may be arranged around (e.g., adjacent to) the transmission area TA, but in other embodiments, the first non-display area NDA1 around the transmission area TA may be omitted as needed or desired. In other words, the transmission area TA may be surrounded (e.g., around a periphery thereof) by the display area DA, and the first non-display area NDA1 between the transmission area TA and the display area DA may not be present. For example, a sub-display area in which display elements are arranged, and a transmission portion having a high transmittance without the display elements arranged therein, may be repeatedly arranged in the transmission area TA.

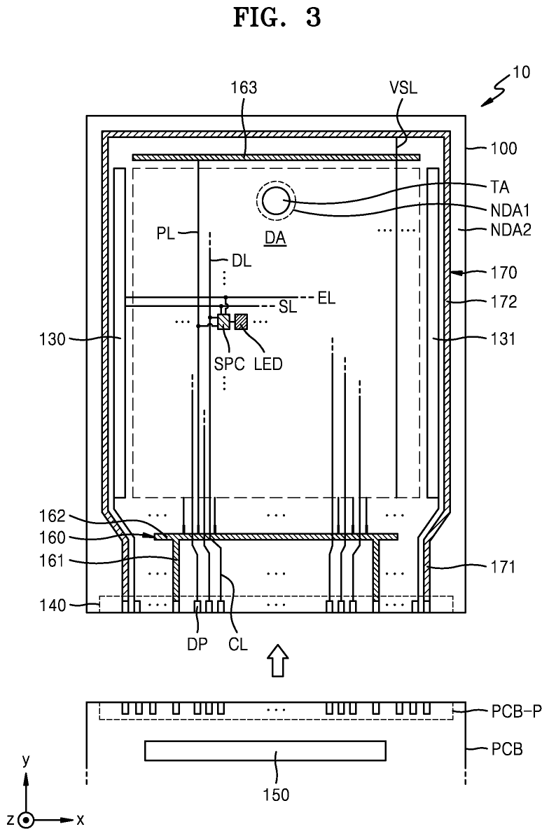

FIG. 3 is a plan view schematically illustrating a display panel 10, according to an embodiment.

Referring to FIG. 3, the display panel 10 may include a transmission area TA, a display area DA, a first non-display area NDA1, and a second non-display area NDA2. The shape of the display panel 10 may be the same or substantially the same as a shape of a substrate 100. For example, it may be understood that the substrate 100 includes the transmission area TA, the first non-display area NDA1, the display area DA, and the second non-display area NDA2.

The transmission area TA may be arranged inside (e.g., within) the display area DA, and may be completely surrounded (e.g., around a periphery thereof) by the display area DA. The transmission area TA may be arranged at the upper center of the display area DA, as illustrated in FIG. 3. In other embodiments, the transmission area TA may be arranged at various suitable positions. For example, the transmission area TA may be arranged at the upper left side of the display area DA, or at the upper right side of the display area DA.

The first non-display area NDA1 may be located between the transmission area TA and the display area DA, and may completely surround (e.g., around a periphery of) the transmission area TA.

The display area DA may be an area on which an image is displayed. The display area DA may have various suitable shapes, for example, such as a circular shape, an elliptical shape, a polygonal shape, or a specific figure shape. FIG. 3 illustrates that the display area DA has a rectangular or substantially rectangular shape with right angled corners, but the present disclosure is not limited thereto. In some embodiments, the display area DA may have a rectangular or substantially rectangular shape with rounded corners.

The display panel 10 may include light-emitting diodes LED arranged in the display area DA, and sub-pixel circuits SPC electrically connected to the light-emitting diodes LED, respectively. The light-emitting diodes LED and the sub-pixel circuits SPC may be arranged along the first direction (e.g., the ±x direction) and the second direction (e.g., the ±y direction) in the display area DA. The sub-pixel circuits SPC may be electrically connected to scan lines SL, emission control lines EL, data lines DL, and driving voltage lines PL, which are arranged in the display area DA.

The scan lines SL and the emission control lines EL may extend in the first direction (e.g., the ±x direction), and may be electrically connected to the sub-pixel circuits SPC located at (e.g., in or on) the same row as each other. The data lines DL and the driving voltage lines PL may extend in the second direction (e.g., the ±y direction), and may be electrically connected to the sub-pixel circuits SPC located at (e.g., in or on) the same column as each other.

The second non-display area NDA2 may be outside the display area DA. For example, the second non-display area NDA2 may completely surround (e.g., around a periphery of) the display area DA.

The display panel 10 may include a first gate driving circuit 130, a second gate driving circuit 131, a first voltage supply line 160, a second voltage supply line 170, and a pad portion 140, which are arranged in the second non-display area NDA2.

The first gate driving circuit 130 and the second gate driving circuit 131 may include a scan driving circuit and an emission control driving circuit. The scan driving circuit may provide scan signals to the sub-pixel circuits SPC through the scan lines SL. The emission control driving circuit may provide emission control signals to the sub-pixel circuits SPC through the emission control lines EL.

The second gate driving circuit 131 may be arranged in parallel or substantially in parallel with the first gate driving circuit 130 with the display area DA therebetween. Some of the sub-pixel circuits SPC arranged in the display area DA may be electrically connected to the first gate driving circuit 130, and the other remaining sub-pixel circuits SPC may be electrically connected to the second gate driving circuit 131. In another embodiment, the second gate driving circuit 131 may be omitted as needed or desired.

The first voltage supply line 160 and the second voltage supply line 170 may be arranged in the second non-display area NDA2. The first voltage supply line 160 may include a first sub-line 161 extending in the second direction (e.g., the ±y direction) toward an end portion of the substrate 100, and a second sub-line 162 and a third sub-line 163 extending in parallel or substantially in parallel with each other in the first direction (e.g., the ±x direction) with the display area DA therebetween. The second voltage supply line 170 may partially surround (e.g., around a periphery of) the display area DA in a loop shape having one open side. The second voltage supply line 170 may include a first sub-line 171 extending in the second direction (e.g., the ±y direction) toward the end portion of the substrate 100, and a second sub-line 172 extending along an edge of the display area DA.

The pad portion 140 may be arranged at one side of the second non-display area NDA2. The pad portion 140 may include a plurality of pads, such as a plurality of data pads DP. The pad portion 140 may be exposed without being covered by an insulating layer, and may be electrically connected to a printed circuit board PCB. The pads of the pad portion 140 may be electrically connected to a terminal portion PCB-P of the printed circuit board PCB. The printed circuit board PCB may transmit signals or voltages from a controller to the display panel 10.

Control signals, which are generated by the controller, may be transmitted to the first gate driving circuit 130 and the second gate driving circuit 131 through the printed circuit board PCB and the pad portion 140.

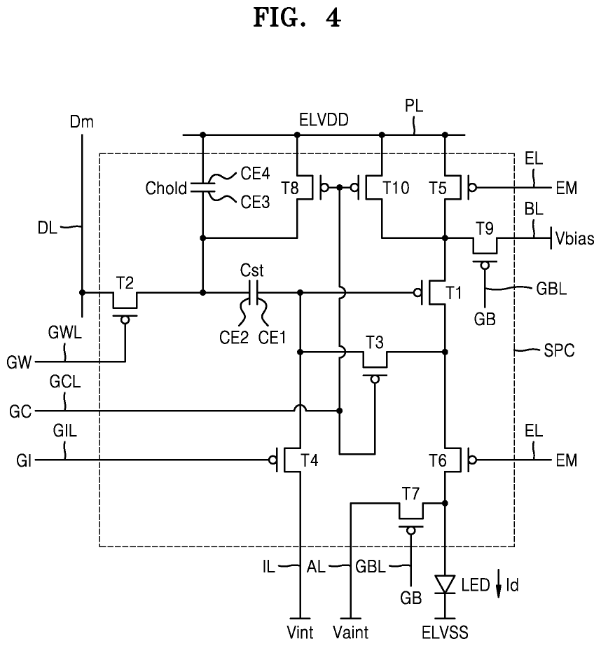

A first driving voltage (or a first power supply voltage) (e.g., see ELVDD of FIG. 4), which may be generated by the controller, may be transmitted to the first voltage supply line 160 through the first sub-line 161 connected to a pad of the pad portion 140. The first driving voltage ELVDD may be provided to the sub-pixel circuits SPC through a driving voltage line PL connected to the first voltage supply line 160.

A second driving voltage (e.g., see ELVSS of FIG. 4), which may be generated by the controller, may be transmitted to the second voltage supply line 170 through the first sub-line 171 connected to a pad of the pad portion 140. The second driving voltage ELVSS may be provided to an opposite electrode (e.g., a cathode) of the light-emitting diode LED connected to the second voltage supply line 170. Common voltage lines VSL electrically connected to the second voltage supply line 170 may be arranged in the display area DA. The common voltage lines VSL may prevent or substantially prevent a voltage drop in the second driving voltage ELVSS that may occur as the area of the display area DA is increased.

A data driving circuit 150 may be electrically connected to the data lines DL. A data signal (or a data voltage) of the data driving circuit 150 may be provided to the sub-pixel circuits SPC through a connection line CL connected to a data pad DP of the pad portion 140 and the data line DL connected to the connection line CL.

FIG. 3 illustrates that the data driving circuit 150 is disposed on the printed circuit board PCB, but the present disclosure is not limited thereto, and in another embodiment, the data driving circuit 150 may be disposed on the substrate 100. For example, the data driving circuit 150 may be located between the pad portion 140 and the first voltage supply line 160.

FIG. 4 is an equivalent circuit diagram illustrating a sub-pixel on a display panel, according to an embodiment.

Referring to FIG. 4, a sub-pixel circuit SPC that is electrically connected to a light-emitting diode LED may include at least one transistor, and at least one capacitor. The light-emitting diode LED may include a pixel electrode (e.g., an anode), an opposite electrode (e.g., a cathode), and an intermediate layer between the pixel electrode and the opposite electrode. The intermediate layer may include an emission layer. The pixel electrode of the light-emitting diode LED may be electrically connected to the sub-pixel circuit SPC, and the opposite electrode may be electrically connected to the common voltage line (e.g., see VSL of FIG. 3) and/or the second voltage supply line (e.g., see 170 of FIG. 3) through which the second driving voltage ELVSS is provided.

As an example, the sub-pixel circuit SPC may include first to tenth transistors T1 to T10, a first capacitor Cst, and a second capacitor Chold.

The sub-pixel circuit SPC may be electrically connected to first to fourth scan lines GWL, GCL, GIL, and GBL for transmitting first to fourth scan signals GW, GC, GI, and GB, respectively, a data line DL for transmitting a data voltage Dm, an emission control line EL for transmitting an emission control signal EM, a driving voltage line PL for transmitting a first driving voltage ELVDD, a first initialization voltage line IL for transmitting a first initialization voltage Vint, a second initialization voltage line AL for transmitting a second initialization voltage Vaint, and a bias voltage line BL for transmitting a bias voltage Vbias.

The first transistor T1 may be a driving transistor in which an amount of a drain current is determined according to a gate-source voltage. The second to tenth transistors T2 to T10 may each be a switching transistor to be turned on/off according to a gate-source voltage and a gate voltage or substantially the gate voltage. The first to tenth transistors T1 to T10 may each be provided as a thin-film transistor.

The first capacitor Cst and the second capacitor Chold may be electrically connected to the driving voltage line PL and a gate electrode of the first transistor T1. The first capacitor Cst may be a storage capacitor, and may include a first lower electrode CE1 electrically connected to the gate electrode of the first transistor T1, and a first upper electrode CE2 overlapping with the first lower electrode CE1. The second capacitor Chold may include a second lower electrode CE3 electrically connected to the first upper electrode CE2 of the first capacitor Cst, and a second upper electrode CE4 connected to the driving voltage line PL.

The first transistor T1 may control the amount of the driving current Id flowing from the driving voltage line PL to the light-emitting diode LED according to the gate-source voltage. The first transistor T1 may include the gate electrode connected to the first lower electrode CE1 of the first capacitor Cst, a source electrode connected to the driving voltage line PL through the fifth transistor T5, and a drain electrode connected to the light-emitting diode LED through the sixth transistor T6. The second transistor T2 may electrically connect the data line DL to the first upper electrode CE2 of the first capacitor Cst (e.g., and/or to the second lower electrode CE3 of the second capacitor Chold) in response to the first scan signal GW. The second transistor T2 may transmit the data voltage Dm to the first upper electrode CE2 of the first capacitor Cst (e.g., and/or to the second lower electrode CE3 of the second capacitor Chold) in response to the first scan signal GW.

The third transistor T3 may electrically connect the drain electrode of the first transistor T1 and the gate electrode of the first transistor T1 to each other in response to the second scan signal GC. The third transistor T3 may be connected in series between the drain electrode of the first transistor T1 and the gate electrode of the first transistor T1. In other words, the third transistor T3 may be turned on to diode-connect the first transistor T1.

The fourth transistor T4 may electrically connect the first initialization voltage line IL to the gate electrode of the first transistor T1 in response to the third scan signal Gl. The fourth transistor T4 may apply the first initialization voltage Vint to the gate electrode of the first transistor T1 in response to the third scan signal GI.

The fifth transistor T5 may electrically connect the driving voltage line PL to the source electrode of the first transistor T1 in response to the emission control signal EM. The fifth transistor T5 may apply the first driving voltage ELVDD to the source electrode of the first transistor T1 in response to the emission control signal EM.

The sixth transistor T6 may connect the drain electrode of the first transistor T1 to the pixel electrode (e.g., the anode) of the light-emitting diode LED in response to the emission control signal EM. The sixth transistor T6 may electrically connect the drain electrode of the first transistor T1 to the pixel electrode (e.g., the anode) of the light-emitting diode LED in response to the emission control signal EM.

FIG. 4 illustrates that the fifth transistor T5 and the sixth transistor T6 operate in response to the same emission control signal EM as each other, but the present disclosure is not limited thereto, and in another embodiment, the fifth transistor T5 and the sixth transistor T6 may operate in response to different emission control signals from each other. For example, the fifth transistor T5 may have a gate electrode connected to a first emission control line, and may electrically connect the driving voltage line PL to the source electrode of the first transistor T1 in response to a first emission control signal. The sixth transistor T6 may have a gate electrode connected to a second emission control line, and may electrically connect the drain electrode of the first transistor T1 to the pixel electrode (e.g., the anode) of the light-emitting diode LED in response to a second emission control signal.

The seventh transistor T7 may electrically connect the second initialization voltage line AL to the pixel electrode (e.g., the anode) of the light-emitting diode LED in response to the fourth scan signal GB. The seventh transistor T7 may apply the second initialization voltage Vaint to the pixel electrode (e.g., the anode) of the light-emitting diode LED in response to the fourth scan signal GB.

The eighth transistor T8 may electrically connect the driving voltage line PL to the first upper electrode CE2 of the first capacitor Cst and/or to the second lower electrode CE3 of the second capacitor Chold in response to the second scan signal GC. The eighth transistor T8 may be apply the first driving voltage ELVDD to the first upper electrode CE2 of the first capacitor Cst and/or to the second lower electrode CE3 of the second capacitor Chold in response to the second scan signal GC.

The ninth transistor T9 may electrically connect the bias voltage line BL to the source electrode of the first transistor T1 in response to the fourth scan signal GB. The ninth transistor T9 may apply the bias voltage Vbias to the source electrode of the first transistor T1 in response to the fourth scan signal GB.

The tenth transistor T10 may electrically connect the driving voltage line PL to the drain electrode of the fifth transistor T5 in response to the second scan signal GC.

FIG. 4 illustrates that the seventh transistor T7 and the ninth transistor T9 operate in response to the same fourth scan signal GB as each other, but the present disclosure is not limited thereto, and in another embodiment, the seventh transistor T7 and the ninth transistor T9 may operate in response to different scan signals from each other.

The second scan signal GC may be synchronized or substantially synchronized with the first scan signal GW. The third scan signal GI may be synchronized or substantially synchronized with the first scan signal GW of a previous row. The fourth scan signal GB may be synchronized or substantially synchronized with the first scan signal GW. In another embodiment, the fourth scan signal GB may be synchronized or substantially synchronized with the first scan signal GW of a next row, or with the third scan signal GI of the next row.

In an embodiment, the first to tenth transistors T1 to T10 may each include a semiconductor layer including silicon. For example, the first to tenth transistors T1 to T10 may each include a semiconductor layer including low temperature polysilicon (LTPS). Polysilicon may have high electron mobility (e.g., 100 cm²/Vs or more), low energy consumption, and excellent reliability.

In another embodiment, the first to tenth transistors T1 and T10 may each include an oxide of at least one selected from among indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and/or zinc (Zn). For example, the semiconductor layer may be an InSnZnO (ITZO) semiconductor layer, an InGaZnO (IGZO) semiconductor layer, or the like.

In another embodiment, some of the semiconductor layers of the first to tenth transistors T1 to T10 may each include LTPS, and others of the semiconductor layers of the first to tenth transistors T1 to T10 may each include an oxide semiconductor (e.g., IGZO and/or the like).

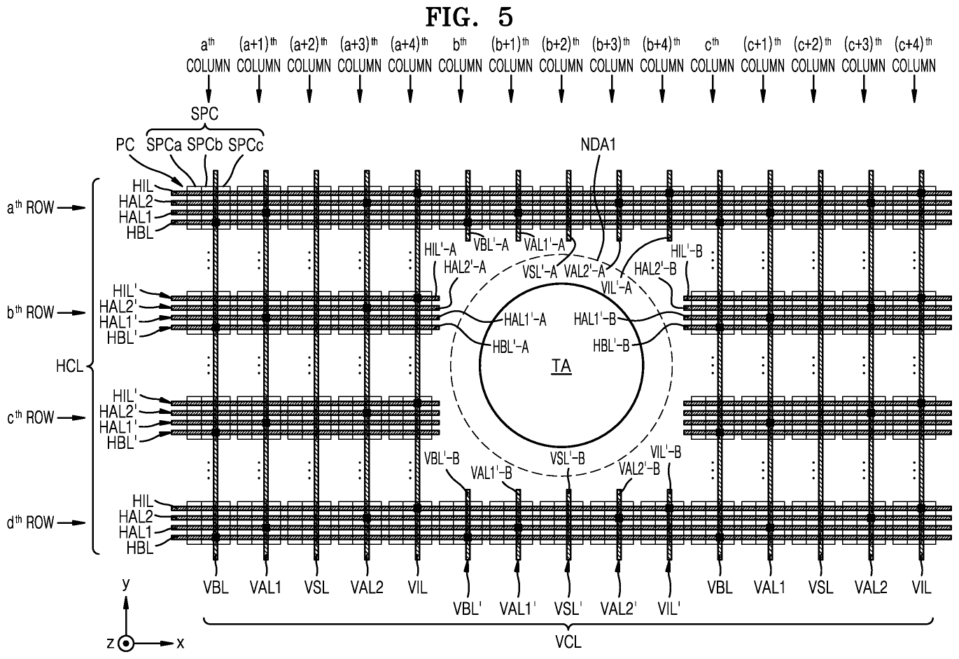

FIG. 5 is a plan view schematically illustrating pixel circuits and lines on a display panel, according to an embodiment.

Sub-pixel circuits SPC may be electrically connected to light-emitting diodes, respectively. Hereinafter, for convenience, the sub-pixel circuits SPC that are respectively electrically connected to first to third light-emitting diodes configured to emit light of different colors from each other may be referred to as first to third sub-pixel circuits SPCa, SPCb, and SPCc. The first sub-pixel circuit SPCa may be electrically connected to the first light-emitting diode configured to emit light of a first color (e.g., red). The second sub-pixel circuit SPCb may be electrically connected to the second light-emitting diode configured to emit light of a second color (e.g., green). The third sub-pixel circuit SPCc may be electrically connected to the third light-emitting diode configured to emit light of a third color (e.g., blue). The first to third sub-pixel circuits SPCa, SPCb, and SPCc may be repeatedly arranged along the first direction (e.g., the ±x direction). The first to third sub-pixel circuits SPCa, SPCb, and SPCc that are adjacent to each other in the first direction (e.g., the ±x direction) may be referred to as a pixel circuit PC.

In the display area DA, the pixel circuits PC may be arranged in a matrix form along the first direction (e.g., the ±x direction) and the second direction (e.g., the ±y direction). For example, an array of a plurality of pixel circuits PC arranged along a plurality of rows and a plurality of columns may be arranged in the display area DA. The pixel circuit PC may include the first to third sub-pixel circuits SPCa, SPCb, and SPCc that are adjacent to each other in the first direction (e.g., the ±x direction).

The pixel circuits PC arranged in an a^{th} row may be located in the upward direction (e.g., the ±y direction) from the transmission area TA in a plan view. The transmission area TA may be arranged at (e.g., in or on) b^{th} and c^{th} rows. A portion of the transmission area TA may be arranged along a straight line in the first direction (e.g., the ±x direction) with the pixel circuits PC arranged in the b^{th} row. A portion of the transmission area TA may be arranged along a straight line in the first direction (e.g., the ±x direction) with the pixel circuits PC arranged in the c^{th} row. The pixel circuits PC arranged in the b^{th} and c^{th} rows and the transmission area TA may be arranged along the first direction (e.g., the ±x direction). The pixel circuits PC arranged in a d^{th} row may be located in the downward direction (e.g., the −y direction) from the transmission area TA in a plan view. The a^{th} and d^{th} rows may be rows that are closest to the transmission area TA from among a plurality of rows that do not include the transmission area TA (e.g., that are not arranged along a straight line in the first direction with respect to the transmission area TA). A plurality of rows may be located between the a^{th} row and the b^{th} row. A plurality of rows may be located between the b^{th} row and the c^{th} row. A plurality of rows may be located between the c^{th} row and the d^{th} row.

The pixel circuits PC arranged in an a^{th} column, an (a+1)^{th} column, an (a+2)^{th} column, an (a+3)^{th} column, and an (a+4)^{th} column may be arranged in the left direction (e.g., the −x direction) from the transmission area TA in a plan view. The pixel circuits PC arranged in a b^{th} column, a (b+1)^{th} column, a (b+2)^{th} column, a (b+3)^{th} column, and a (b+4)^{th} column may be arranged along a straight line in the second direction (e.g., the ±y direction) with the transmission area TA. The pixel circuits PC arranged in a c^{th} column, a (c+1)^{th} column, a (c+2)^{th} column, a (c+3)^{th} column, and a (c+4)^{th} column may be arranged in the right direction (e.g., the +x direction) from the transmission area TA in a plan view. The (a+4)^{th} column and the c^{th} column may be columns that are closest to the transmission area TA from among a plurality of columns that do not include the transmission area TA (e.g., that are not arranged along a straight line in the second direction with respect to the transmission area TA). In addition, FIG. 5 illustrates that the (a+4)^{th} column and the b^{th} column are adjacent to each other, and the (b+4)^{th} column and the c^{th} column are adjacent to each other, but the present disclosure is limited thereto. A plurality of columns may be located between the (a+4)^{th} column and the b^{th} column, and a plurality of columns may be located between the (b+4)^{th} column and the c^{th} column.

The pixel circuits PC arranged in the a^{th} column and the pixel circuits PC arranged in the c^{th} column may be spaced apart from each other in the first direction (e.g., the ±x direction) with the transmission area TA therebetween. The pixel circuits PC arranged in the (a+1)^{th} column and the pixel circuits PC arranged in the (c+1)^{th} column may be spaced apart from each other in the first direction (e.g., the ±x direction) with the transmission area TA therebetween. The pixel circuits PC arranged in the (a+2)^{th} column and the pixel circuits PC arranged in the (c+2)^{th} column may be spaced apart from each other in the first direction (e.g., the ±x direction) with the transmission area TA therebetween. The pixel circuits PC arranged in the (a+3)^{th} column and the pixel circuits PC arranged in the (c+3)^{th} column may be spaced apart from each other in the first direction (e.g., the ±x direction) with the transmission area TA therebetween. The pixel circuits PC arranged in the (a+4)^{th} column and the pixel circuits PC arranged in the (c+4)^{th} column may be spaced apart from each other in the first direction (e.g., the ±x direction) with the transmission area TA therebetween.

Conductive lines electrically connected to the sub-pixel circuits SPC, for example, such as first conductive lines (hereinafter referred to as horizontal conductive lines HCL) extending in the first direction (e.g., the ±x direction) and second conductive lines (hereinafter referred to as vertical conductive lines VCL) extending in the second direction (e.g., the ±y direction), may be arranged in the display area DA. The horizontal conductive lines HCL may extend in the first direction (e.g., the ±x direction), and may be arranged along the second direction (e.g., the ±y direction) crossing the first direction. The vertical conductive lines VCL may extend in the second direction (e.g., the ±y direction), and may be arranged along the first direction (e.g., the ±x direction).

The horizontal conductive lines HCL extending in the first direction (e.g., the ±x direction) may include horizontal bias voltage lines HBL and HBL′, first horizontal initialization voltage lines HIL and HIL′, second horizontal initialization voltage lines HAL1 and HAL1′, and third horizontal initialization voltage lines HAL2 and HAL2′.

The pixel circuits PC arranged in one of the rows may overlap with one horizontal bias voltage line HBL or HBL′, one first horizontal initialization voltage line HIL or HIL′, one second horizontal initialization voltage line HAL1 or HAL1′, and one third horizontal initialization voltage line HAL2 or HAL2′.

A first horizontal bias voltage line HBL may overlap with the pixel circuits PC arranged in the row (e.g., the a^{th} row or the d^{th} row) that is not arranged on a straight line in the first direction with respect to the transmission area TA. A second horizontal bias voltage line HBL′ may overlap with the pixel circuits PC arranged in the row (e.g., the b^{th} row or the c^{th} row) that is arranged on a straight line in the first direction with respect to the transmission area TA. The bias voltage line BL illustrated in FIG. 4 may be the first horizontal bias voltage line HBL or the second horizontal bias voltage line HBL′.

A 1^{st}-1 horizontal initialization voltage line HIL may overlap with the pixel circuits PC arranged in the row (e.g., the a^{th} row or the d^{th} row) that is not arranged on a straight line in the first direction with respect to the transmission area TA. A 1^{st}-2 horizontal initialization voltage line HIL′ may overlap with the pixel circuits PC arranged in the row (e.g., the b^{th} row or the c^{th} row) that is arranged on a straight line in the first direction with respect to the transmission area TA. The first initialization voltage line IL illustrated in FIG. 4 may be the 1^{st}-1 horizontal initialization voltage line HIL or the 1^{st}-2 horizontal initialization voltage line HIL′.

A 2^{nd}-1 horizontal initialization voltage line HAL1 may overlap with the pixel circuits PC arranged in the row (e.g., the a^{th} row or the d^{th} row) that is not arranged on a straight line in the first direction with respect to the transmission area TA. A 2^{nd}-2 horizontal initialization voltage line HAL1′ may overlap with the pixel circuits PC arranged in the row (e.g., the b^{th} row or the c^{th} row) that is arranged on a straight line in the first direction with respect to the transmission area TA. The second initialization voltage line AL illustrated in FIG. 4 may be the 2^{nd}-1 horizontal initialization voltage line HAL1 or the 2^{nd}-2 horizontal initialization voltage line HAL1′.

A 3^{rd}-1 horizontal initialization voltage line HAL2 may overlap with the pixel circuits PC arranged in the row (e.g., the a^{th} row or the d^{th} row) that is not arranged on a straight line in the first direction with respect to the transmission area TA. A 3^{rd}-2 horizontal initialization voltage line HAL2′ may overlap with the pixel circuits PC arranged in the row (e.g., the b^{th} row or the c^{th} row) that is arranged on a straight line in the first direction with respect to the transmission area TA. A third initialization voltage line may be the 3^{rd}-1 horizontal initialization voltage line HAL2 or the 3^{rd}-2 horizontal initialization voltage line HAL2′.

The vertical conductive lines VCL extending in the second direction (e.g., the ±y direction) may include vertical bias voltage lines VBL and VBL′, first vertical initialization voltage lines VIL and VIL′, second vertical initialization voltage lines VAL1 and VAL1′, third vertical initialization voltage lines VAL2 and VAL2′, and common voltage lines VSL and VSL′.

One vertical conductive line VCL may overlap with the pixel circuits PC arranged in one of the columns. In other words, the pixel circuits PC arranged in one of the columns may overlap with only one of the vertical bias voltage lines VBL and VBL′, the first vertical initialization voltage lines VIL and VIL′, the second vertical initialization voltage lines VAL1 and VAL1′, the third vertical initialization voltage lines VAL2 and VAL2′, and/or the common voltage lines VSL and VSL′.

In an embodiment, the vertical bias voltage lines VBL and VBL′, the first vertical initialization voltage lines VIL and VIL′, the second vertical initialization voltage lines VAL1 and VAL1′, the third vertical initialization voltage lines VAL2 and VAL2′, and the common voltage lines VSL and VSL′ may be repeatedly arranged along the first direction (e.g., the ±x direction). For example, the vertical bias voltage lines VBL and VBL′ may overlap with the pixel circuits PC arranged in a (5n+1)^{th} column, the second vertical initialization voltage lines VAL1 and VAL1′ may overlap with the pixel circuits PC arranged in a (5n+2)^{th} column, the common voltage lines VSL and VSL′ may overlap with the pixel circuits PC arranged in a (5n+3)^{th} column, the third vertical initialization voltage lines VAL2 and VAL2′ may overlap with the pixel circuits PC arranged in a (5n+4)^{th} column, and the first vertical initialization voltage lines VIL and VIL′ may overlap with the pixel circuits PC arranged in a (5n+5)^{th} column (where n is an integer greater than or equal to 0). However, the present disclosure is not limited thereto, and the arrangement relationship of the vertical bias voltage lines VBL and VBL′, the first vertical initialization voltage lines VIL and VIL′, the second vertical initialization voltage lines VAL1 and VAL1′, the third vertical initialization voltage lines VAL2 and VAL2′, and the common voltage lines VSL and VSL′ may be variously modified as needed or desired.

A first vertical bias voltage line VBL may overlap with the pixel circuits PC arranged in the column (e.g., the a^{th} column or the c^{th} column) that is not arranged on a straight line in the second direction with respect to the transmission area TA. A second vertical bias voltage line VBL′ may overlap with the pixel circuits PC arranged in the column (e.g., the b^{th} column) that is arranged on a straight line in the second direction with respect to the transmission area TA.

A 1^{st}-1 vertical initialization voltage line VIL may overlap with the pixel circuits PC arranged in the column (e.g., the (a+4)^{th} column or the (c+4)^{th} column) that is not arranged on a straight line in the second direction with respect to the transmission area TA. A 1^{st}-2 vertical initialization voltage line VIL′ may overlap with the pixel circuits PC arranged in the column (e.g., the (b+4)^{th} column) that is arranged on a straight line in the second direction with respect to the transmission area TA.

A 2^{nd}-1 vertical initialization voltage line VAL1 may overlap with the pixel circuits PC arranged in the column (e.g., the (a+1)^{th} column or the (c+1)^{th} column) that is not arranged on a straight line in the second direction with respect to the transmission area TA. A 2^{nd}-2 vertical initialization voltage line VAL1′ may overlap with the pixel circuits PC arranged in the column (e.g., the (b+1)^{th} column) that is arranged on a straight line in the second direction with respect to the transmission area TA.

A 3^{rd}-1 vertical initialization voltage line VAL2 may overlap with the pixel circuits PC arranged in the column (e.g., the (a+3)^{th} column or the (c+3)^{th} column) that is not arranged on a straight line in the second direction with respect to the transmission area TA. A 3^{rd}-2 vertical initialization voltage line VAL2′ may overlap with the pixel circuits PC arranged in the column (e.g., the (b+3)^{th} column) that is arranged on a straight line in the second direction with respect to the transmission area TA.

A first common voltage line VSL may overlap with the pixel circuits PC arranged in the column (e.g., the (a+2)^{th} column or the (c+2)^{th} column) that is not arranged on a straight line in the second direction with respect to the transmission area TA. A second common voltage line VSL′ may overlap with the pixel circuits PC arranged in the column (e.g., the (b+2)^{th} column) that is arranged on a straight line in the second direction with respect to the transmission area TA.

Hereinafter, for convenience, the arrangement and connection relationships of the pixel circuits PCs and the lines included in the display panel 10 may be described in more detail with respect to the pixel circuits PC arranged in the a^{th} row and the b^{th} row, and the horizontal conductive lines HCL and the vertical conductive lines VCL overlapping with the pixel circuits PC.

The first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2 may overlap with the pixel circuits PC arranged in the a^{th} row. The first horizontal bias voltage line HBL may transmit the bias voltage (e.g., see Vbias of FIG. 4) to the first to third sub-pixel circuits SPCa, SPCb, and SPCc included in each of the pixel circuits PC arranged in the a^{th} row. The 1^{st}-1 horizontal initialization voltage line HIL may transmit the first initialization voltage (e.g., see Vint of FIG. 4) to the first to third sub-pixel circuits SPCa, SPCb, and SPCc included in each of the pixel circuits PC arranged in the a^{th} row. The 2^{nd}-1 horizontal initialization voltage line HAL1 may transmit the second initialization voltage (e.g., see Vaint of FIG. 4) to the first and third sub-pixel circuits SPCa and SPCc included in each of the pixel circuits PC arranged in the a^{th} row. The 3^{rd}-1 horizontal initialization voltage line HAL2 may transmit the second initialization voltage (e.g., see Vaint of FIG. 4) to the second sub-pixel circuits SPCb included in each of the pixel circuits PC arranged in the a^{th} row. In some embodiments, the 3^{rd}-1 horizontal initialization voltage line HAL2 may be omitted as needed or desired, and the 2^{nd}-1 horizontal initialization voltage line HAL1 may transmit the second initialization voltage (e.g., see Vaint of FIG. 4) to all of the first to third sub-pixel circuits SPCa, SPCb, and SPCc included in each of the pixel circuits PC arranged in the a^{th} row.

The first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2 may not be arranged on a straight line in the first direction (e.g., the ±x direction) with respect to the transmission area TA. The first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2 may be spaced apart from the transmission area TA in the second direction (e.g., the +y direction). Accordingly, each of the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2 may continuously extend in the first direction (e.g., the ±x direction) without being disconnected.

The second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′ may overlap with the pixel circuits PC arranged in the b^{th} row. The second horizontal bias voltage line HBL′ may transmit the bias voltage (e.g., see Vbias of FIG. 4) to the first to third sub-pixel circuits SPCa, SPCb, and SPCc included in each of the pixel circuits PC arranged in the b^{th} row. The 1^{st}-2 horizontal initialization voltage line HIL′ may transmit the first initialization voltage (e.g., see Vint of FIG. 4) to the first to third sub-pixel circuits SPCa, SPCb, and SPCc included in each of the pixel circuits PC arranged in the b^{th} row. The 2^{nd}-2 horizontal initialization voltage line HAL1′ may transmit the second initialization voltage (e.g., see Vaint of FIG. 4) to the first and third sub-pixel circuits SPCa and SPCc included in each of the pixel circuits PC arranged in the b^{th} row. The 3^{rd}-2 horizontal initialization voltage line HAL2′ may transmit the second initialization voltage (e.g., see Vaint of FIG. 4) to the second sub-pixel circuits SPCb included in each of the pixel circuits PC arranged in the b^{th} row. In some embodiments, the 3^{rd}-2 horizontal initialization voltage line HAL2′ may be omitted as needed or desired, and the 2^{nd}-2 horizontal initialization voltage line HAL1′ may transmit the second initialization voltage (e.g., see Vaint of FIG. 4) to all of the first to third sub-pixel circuits SPCa, SPCb, and SPCc included in each of the pixel circuits PC arranged in the b^{th} row.

The second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′ may be arranged on a straight line in the first direction (e.g., the ±x direction) with respect to the transmission area TA. Each of the second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′ may be disconnected around (e.g., adjacent to) the transmission area TA.

The second horizontal bias voltage line HBL′ may include a first portion HBL′-A and a second portion HBL′-B that are spaced apart from each other in the first direction (e.g., the ±x direction) with the transmission area TA therebetween. The first portion HBL′-A and the second portion HBL′-B of the second horizontal bias voltage line HBL′ may each extend in the first direction (e.g., the ±x direction). The first portion HBL′-A of the second horizontal bias voltage line HBL′ may overlap with the pixel circuits PC arranged in the a^{th} column, the (a+1)^{th} column, the (a+2)^{th} column, the (a+3)^{th} column, and the (a+4)^{th} column from among the pixel circuits PC arranged in the b^{th} row or the c^{th} row. The second portion HBL′-B of the second horizontal bias voltage line HBL′ may overlap with the pixel circuits PC arranged in the c^{th} column, the (c+1)^{th} column, the (c+2)^{th} column, the (c+3)^{th} column, and the (c+4)^{th} column from among the pixel circuits PC arranged in the b^{th} row or the c^{th} row.

The 1^{st}-2 horizontal initialization voltage line HIL′ may include a first portion HIL′-A and a second portion HIL′-B that are spaced apart from each other in the first direction (e.g., the ±x direction) with the transmission area TA therebetween. The first portion HIL′-A and the second portion HIL′-B of the 1^{st}-2 horizontal initialization voltage line HIL′ may each extend in the first direction (e.g., the ±x direction). The first portion HIL′-A of the 1^{st}-2 horizontal initialization voltage line HIL′ may overlap with the pixel circuits PC arranged in the a^{th} column, the (a+1)^{th} column, the (a+2)^{th} column, the (a+3)^{th} column, and the (a+4)^{th} column from among the pixel circuits PC arranged in the b^{th} row or the c^{th} row. The second portion HIL′-B of the 1^{st}-2 horizontal initialization voltage line HIL′ may overlap with the pixel circuits PC arranged in the c^{th} column, the (c+1)^{th} column, the (c+2)^{th} column, the (c+3)^{th} column, and the (c+4)^{th} column from among the pixel circuits PC arranged in the b^{th} row or the c^{th} row.

The 2^{nd}-2 horizontal initialization voltage line HAL1′ may include a first portion HAL1′-A and a second portion HAL1′-B that are spaced apart from each other in the first direction (e.g., the ±x direction) with the transmission area TA therebetween. The first portion HAL1′-A and the second portion HAL1′-B may each extend in the first direction (e.g., the ±x direction). The first portion HAL1′-A of the 2^{nd}-2 horizontal initialization voltage line HAL1′ may overlap with the pixel circuits PC arranged in the a^{th} column, the (a+1)^{th} column, the (a+2)^{th} column, the (a+3)^{th} column, and the (a+4)^{th} column from among the pixel circuits PC arranged in the b^{th} row or the c^{th} row. The second portion HAL1′-B of the 2^{nd}-2 horizontal initialization voltage line HAL1′ may overlap with the pixel circuits PC arranged in the c^{th} column, the (c+1)^{th} column, the (c+2)^{th} column, the (c+3)^{th} column, and the (c+4)^{th} column from among the pixel circuits PC arranged in the b^{th} row or the c^{th} row.

The 3^{rd}-2 horizontal initialization voltage line HAL2′ may include a first portion HAL2′-A and a second portion HAL2′-B that are spaced apart from each other in the first direction (e.g., the ±x direction) with the transmission area TA therebetween. The first portion HAL2′-A and the second portion HAL2′-B may each extend in the first direction (e.g., the ±x direction). The first portion HAL2′-A of the 3^{rd}-2 horizontal initialization voltage line HAL2′ may overlap with the pixel circuits PC arranged in the a^{th} column, the (a+1)^{th} column, the (a+2)^{th} column, the (a+3)^{th} column, and the (a+4)^{th} column from among the pixel circuits PC arranged in the b^{th} row or the c^{th} row. The second portion HAL2′-B of the 3^{rd}-2 horizontal initialization voltage line HAL2′ may overlap with the pixel circuits PC arranged in the c^{th} column, the (c+1)^{th} column, the (c+2)^{th} column, the (c+3)^{th} column, and the (c+4)^{th} column from among the pixel circuits PC arranged in the b^{th} row or the c^{th} row.

The first vertical bias voltage line VBL may overlap with the pixel circuits PC arranged in the a^{th} column. The first vertical bias voltage line VBL may not be arranged on a straight line in the second direction (e.g., the ±y direction) with respect to the transmission area TA. Accordingly, the first vertical bias voltage line VBL may continuously extend in the second direction (e.g., the ±y direction) without being disconnected.

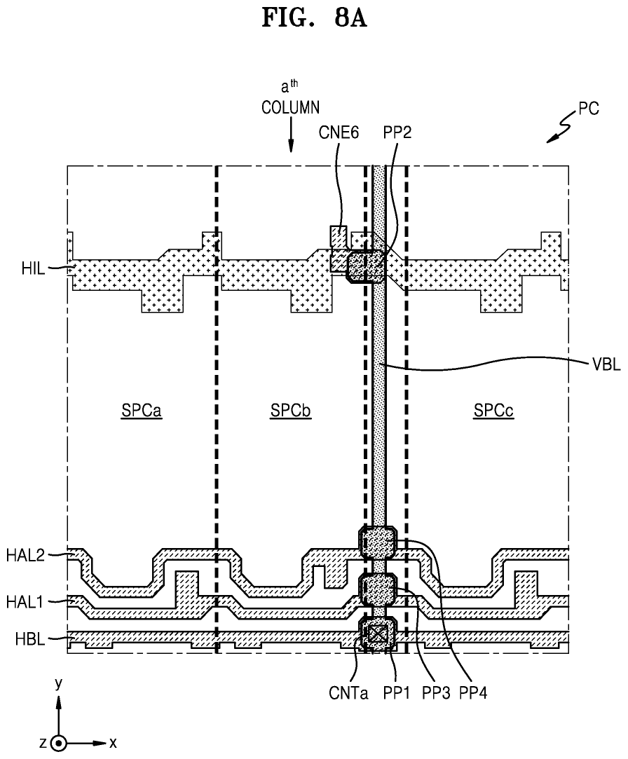

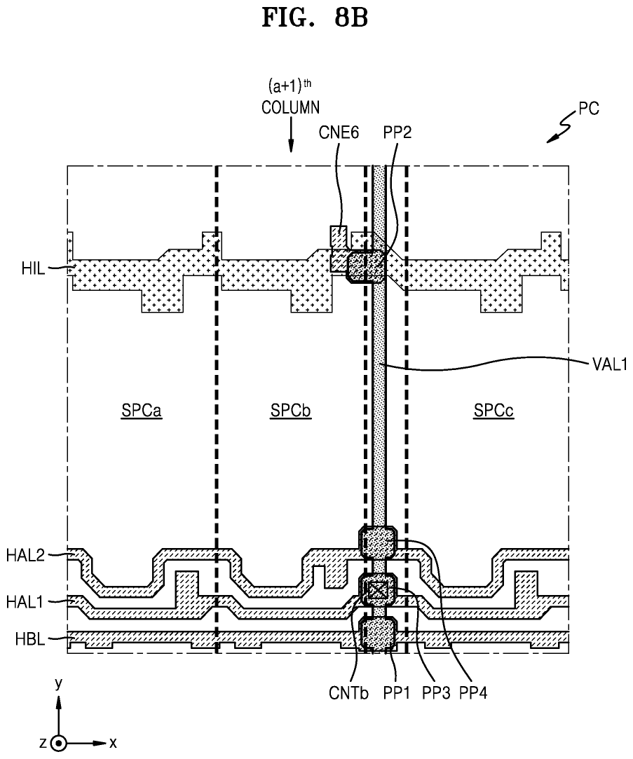

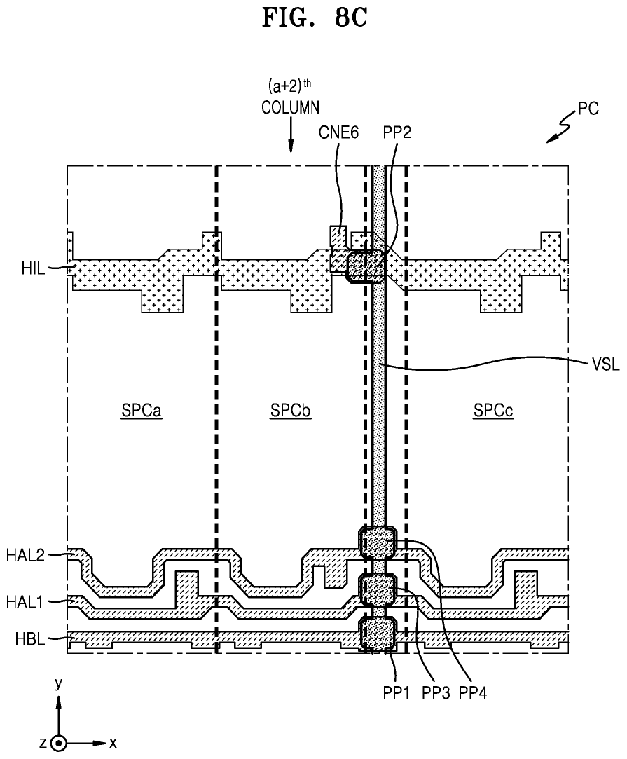

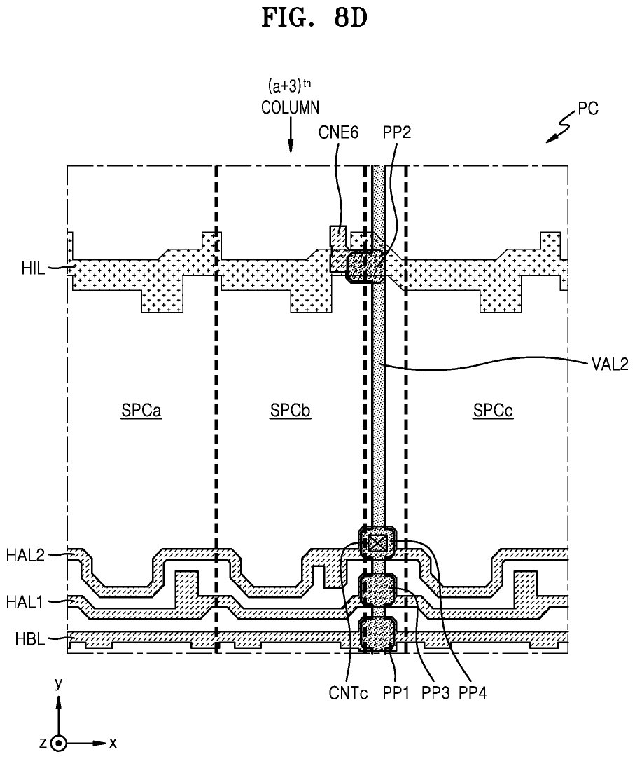

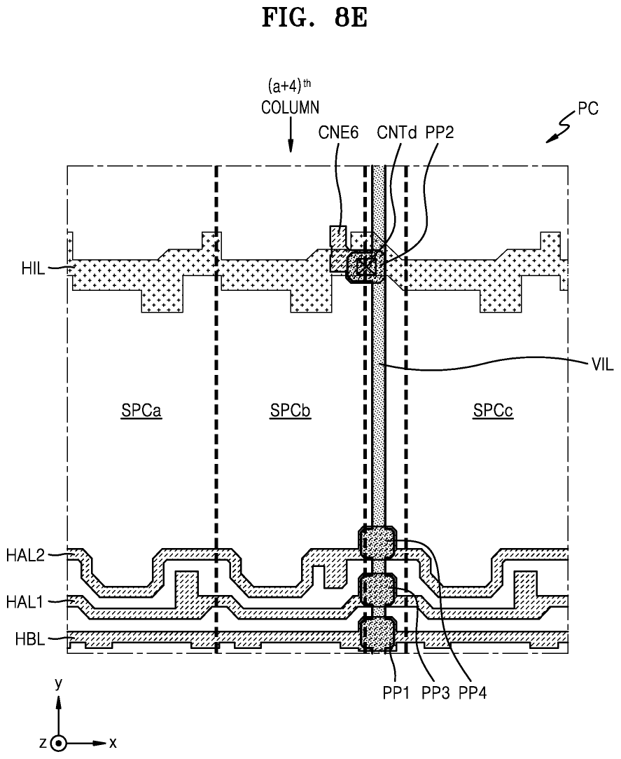

The first vertical bias voltage line VBL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the first portion HBL′-A of the second horizontal bias voltage line HBL′, the first portion HIL′-A of the 1^{st}-2 horizontal initialization voltage line HIL′, the first portion HAL1′-A of the 2^{nd}-2 horizontal initialization voltage line HAL1′, and the first portion HAL2′-A of the 3^{rd}-2 horizontal initialization voltage line HAL2′. The first vertical bias voltage line VBL may be electrically connected to only the first horizontal bias voltage line HBL and the first portions HBL′-A of the second horizontal bias voltage line HBL′ from among the overlapping horizontal conductive lines HCL, and may be electrically isolated from the other remaining lines. This will be described in more detail below with reference to FIG. 8A.

The 2^{nd}-1 vertical initialization voltage line VAL1 may overlap with the pixel circuits PC arranged in the (a+1)^{th} column. The 2^{nd}-1 vertical initialization voltage line VAL1 may not be arranged on a straight line in the second direction (e.g., the ±y direction) with respect to the transmission area TA. Accordingly, the 2^{nd}-1 vertical initialization voltage line VAL1 may continuously extend in the second direction (e.g., the ±y direction) without being disconnected.

The 2^{nd}-1 vertical initialization voltage line VAL1 may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the first portion HBL′-A of the second horizontal bias voltage line HBL′, the first portion HIL′-A of the 1^{st}-2 horizontal initialization voltage line HIL′, the first portion HAL1′-A of the 2^{nd}-2 horizontal initialization voltage line HAL1′, and the first portion HAL2′-A of the 3^{rd}-2 horizontal initialization voltage line HAL2′. The 2^{nd}-1 vertical initialization voltage line VAL1 may be electrically connected to only the 2^{nd}-1 horizontal initialization voltage line HAL1 and the first portions HAL1′-A of the 2^{nd}-2 horizontal initialization voltage line HAL1′ from among the overlapping horizontal conductive lines HCL, and may be electrically isolated from the other remaining lines. This will be described in more detail below with reference to FIG. 8B.

The first common voltage line VSL may overlap with the pixel circuits PC arranged in the (a+2)^{th} column. The first common voltage line VSL may not be arranged on a straight line in the second direction (e.g., the ±y direction) with respect to the transmission area TA. Accordingly, the first common voltage line VSL may continuously extend in the second direction (e.g., the ±y direction) without being disconnected.

The first common voltage line VSL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the first portion HBL′-A of the second horizontal bias voltage line HBL′, the first portion HIL′-A of the 1^{st}-2 horizontal initialization voltage line HIL′, the first portion HAL1′-A of the 2^{nd}-2 horizontal initialization voltage line HAL1′, and the first portion HAL2′-A of the 3^{rd}-2 horizontal initialization voltage line HAL2′. The first common voltage line VSL may be electrically connected to the second voltage supply line (e.g., see 170 of FIG. 3), and may be electrically isolated from all of the overlapping horizontal conductive lines HCL. This will be described in more detail below with reference to FIG. 8C.

The 3^{rd}-1 vertical initialization voltage line VAL2 may overlap with the pixel circuits PC arranged in the (a+3)^{th} column. The 3^{rd}-1 vertical initialization voltage line VAL2 may not be arranged on a straight line in the second direction (e.g., the ±y direction) with respect to the transmission area TA. Accordingly, the 3^{rd}-1 vertical initialization voltage line VAL2 may continuously extend in the second direction (e.g., the ±y direction) without being disconnected.

The 3^{rd}-1 vertical initialization voltage line VAL2 may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the first portion HBL′-A of the second horizontal bias voltage line HBL′, the first portion HIL′-A of the 1^{st}-2 horizontal initialization voltage line HIL′, the first portion HAL1′-A of the 2^{nd}-2 horizontal initialization voltage line HAL1′, and the first portion HAL2′-A of the 3^{rd}-2 horizontal initialization voltage line HAL2′. The 3^{rd}-1 vertical initialization voltage line VAL2 may be electrically connected to only the 3^{rd}-1 horizontal initialization voltage line HAL2 and the first portions HAL2′-A of the 3^{rd}-2 horizontal initialization voltage line HAL2′ from among the overlapping horizontal conductive lines HCL, and may be electrically isolated from the other remaining lines. This will be described in more detail below with reference to FIG. 8D.

The 1^{st}-1 vertical initialization voltage line VIL may overlap with the pixel circuits PC arranged in the (a+4)^{th} column. The 1^{st}-1 vertical initialization voltage line VIL may not be arranged on a straight line in the second direction (e.g., the ±y direction) with respect to the transmission area TA. Accordingly, the 1^{st}-1 vertical initialization voltage line VIL may continuously extend in the second direction (e.g., the ±y direction) without being disconnected.

The 1^{st}-1 vertical initialization voltage line VIL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the first portion HBL′-A of the second horizontal bias voltage line HBL′, the first portion HIL′-A of the 1^{st}-2 horizontal initialization voltage line HIL′, the first portion HAL1′-A of the 2^{nd}-2 horizontal initialization voltage line HAL1′, and the first portion HAL2′-A of the 3^{rd}-2 horizontal initialization voltage line HAL2′. The 1^{st}-1 vertical initialization voltage line VIL may be electrically connected to only the 1^{st}-1 horizontal initialization voltage line HIL and the first portions HIL′-A of the 1^{st}-2 horizontal initialization voltage line HIL′ from among the overlapping horizontal conductive lines HCL, and may be electrically isolated from the other remaining lines. This will be described in more detail below with reference to FIG. 8E.

The second vertical bias voltage line VBL′ may overlap with the pixel circuits PC arranged in the b^{th} column. The second vertical bias voltage line VBL′ may be arranged on a straight line in the second direction (e.g., the ±y direction) with respect to the transmission area TA. Accordingly, the second vertical bias voltage line VBL′ may be disconnected around (e.g., adjacent to) the transmission area TA. The second vertical bias voltage line VBL′ may include a first portion VBL′-A and a second portion VBL′-B that are spaced apart from each other in the second direction (e.g., the ±y direction) with the transmission area TA therebetween. The first portion VBL′-A and the second portion VBL′-B may each extend in the second direction (e.g., the ±y direction). The first portion VBL′-A of the second vertical bias voltage line VBL′ may overlap with the pixel circuits PC arranged in the a^{th} row from among the pixel circuits PC arranged in the b^{th} column. The second portion VBL′-B of the second vertical bias voltage line VBL′ may overlap with the pixel circuits PC arranged in the d^{th} row from among the pixel circuits PC arranged in the b^{th} column.

The second vertical bias voltage line VBL′ may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. The second vertical bias voltage line VBL′ may be electrically connected to only the first horizontal bias voltage line HBL from among the overlapping horizontal conductive lines HCL, and may be electrically isolated from the other remaining lines.

The 2^{nd}-2 vertical initialization voltage line VAL1′ may overlap with the pixel circuits PC arranged in the (b+1)^{th} column. The 2^{nd}-2 vertical initialization voltage line VAL1′ may be arranged on a straight line in the second direction (e.g., the ±y direction) with respect to the transmission area TA. Accordingly, the 2^{nd}-2 vertical initialization voltage line VAL1′ may be disconnected around (e.g., adjacent to) the transmission area TA. The 2^{nd}-2 vertical initialization voltage line VAL1′ may include a first portion VAL1′-A and a second portion VAL1′-B that are spaced apart from each other in the second direction (e.g., the ±y direction) with the transmission area TA therebetween. The first portion VAL1′-A and the second portion VAL1′-B may each extend in the second direction (e.g., the ±y direction). The first portion VAL1′-A of the 2^{nd}-2 vertical initialization voltage line VAL1′ may overlap with the pixel circuits PC arranged in the a^{th} row from among the pixel circuits PC arranged in the (b+1)^{th} column. The second portion VAL1′-B of the 2^{nd}-2 vertical initialization voltage line VAL1′ may overlap with the pixel circuits PC arranged in the d^{th} row from among the pixel circuits PC arranged in the (b+1)^{th} column.

The 2^{nd}-2 vertical initialization voltage line VAL1′ may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. The 2^{nd}-2 vertical initialization voltage line VAL1′ may be electrically connected to only the 2^{nd}-1 horizontal initialization voltage line HAL1 from among the overlapping horizontal conductive lines HCL, and may be electrically isolated from the other remaining lines.

The second common voltage line VSL′ may overlap with the pixel circuits PC arranged in the (b+2)^{th} column. The second common voltage line VSL′ may be arranged on a straight line in the second direction (e.g., the ±y direction) with respect to the transmission area TA. Accordingly, the second common voltage line VSL′ may be disconnected around (e.g., adjacent to) the transmission area TA. The second common voltage line VSL′ may include a first portion VSL′-A and a second portion VSL′-B that are spaced apart from each other in the second direction (e.g., the ±y direction) with the transmission area TA therebetween. The first portion VSL′-A and the second portion VSL′-B may each extend in the second direction (e.g., the ±y direction). The first portion VSL′-A of the second common voltage line VSL′ may overlap with the pixel circuits PC arranged in the a^{th} row from among the pixel circuits PC arranged in the (b+2)^{th} column. The second portion VSL′-B of the second common voltage line VSL′ may overlap with the pixel circuits PC arranged in the d^{th} row from among the pixel circuits PC arranged in the (b+2)^{th} column.

The second common voltage line VSL′ may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. The second common voltage line VSL′ may be electrically connected to the second voltage supply line (e.g., see 170 of FIG. 3), and may be electrically isolated from all of the overlapping horizontal conductive lines HCL.

The 3^{rd}-2 vertical initialization voltage line VAL2′ may overlap with the pixel circuits PC arranged in the (b+3)^{th} column. The 3^{rd}-2 vertical initialization voltage line VAL2′ may be arranged on a straight line in the second direction (e.g., the ±y direction) with respect to the transmission area TA. Accordingly, the 3^{rd}-2 vertical initialization voltage line VAL2′ may be disconnected around (e.g., adjacent to) the transmission area TA. The 3^{rd}-2 vertical initialization voltage line VAL2′ may include a first portion VAL2′-A and a second portion VAL2′-B that are spaced apart from each other in the second direction (e.g., the ±y direction) with the transmission area TA therebetween. The first portion VAL2′-A and the second portion VAL2′-B may each extend in the second direction (e.g., the ±y direction). The first portion VAL2′-A of the 3^{rd}-2 vertical initialization voltage line VAL2′ may overlap with the pixel circuits PC arranged in the a^{th} row from among the pixel circuits PC arranged in the (b+3)^{th} column. The second portion VAL2′-B of the 3^{rd}-2 vertical initialization voltage line VAL2′ may overlap with the pixel circuits PC arranged in the d^{th} row from among the pixel circuits PC arranged in the (b+3)^{th} column.

The 3^{rd}-2 vertical initialization voltage line VAL2′ may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. The 3^{rd}-2 vertical initialization voltage line VAL2′ may be electrically connected to only the 3^{rd}-1 horizontal initialization voltage line HAL2 from among the overlapping horizontal conductive lines HCL, and may be electrically isolated from the other remaining lines.

The 1^{st}-2 vertical initialization voltage line VIL′ may overlap with the pixel circuits PC arranged in the (b+4)^{th} column. The 1^{st}-2 vertical initialization voltage line VIL′ may be arranged on a straight line in the second direction (e.g., the ±y direction) with respect to the transmission area TA. Accordingly, the 1^{st}-2 vertical initialization voltage line VIL′ may be disconnected around (e.g., adjacent to) the transmission area TA. The 1^{st}-2 vertical initialization voltage line VIL′ may include a first portion VIL′-A and a second portion VIL′-B that are spaced apart from each other in the second direction (e.g., the ±y direction) with the transmission area TA therebetween. The first portion VIL′-A and the second portion VIL′-B may each extend in the second direction (e.g., the ±y direction). The first portion VIL′-A of the 1^{st}-2 vertical initialization voltage line VIL′ may overlap with the pixel circuits PC arranged in the a^{th} row from among the pixel circuits PC arranged in the (b+4)^{th} column. The second portion VIL′-B of the 1^{st}-2 vertical initialization voltage line VIL′ may overlap with the pixel circuits PC arranged in the d^{th} row from among the pixel circuits PC arranged in the (b+4)^{th} column.

The 1^{st}-2 vertical initialization voltage line VIL′ may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. The 1^{st}-2 vertical initialization voltage line VIL′ may be electrically connected to only the 1^{st}-1 horizontal initialization voltage line HIL from among the overlapping horizontal conductive lines HCL, and may be electrically isolated from the other remaining lines.

The first vertical bias voltage line VBL may overlap with the pixel circuits PC arranged in the c^{th} column. The first vertical bias voltage line VBL may not be arranged on a straight line in the second direction (e.g., the ±y direction) with respect to the transmission area TA. Accordingly, the first vertical bias voltage line VBL may continuously extend in the second direction (e.g., the ±y direction) without being disconnected.

The first vertical bias voltage line VBL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the second portion HBL′-B of the second horizontal bias voltage line HBL′, the second portion HIL′-B of the 1^{st}-2 horizontal initialization voltage line HIL′, the second portion HAL1′-B of the 2^{nd}-2 horizontal initialization voltage line HAL1′, and the second portion HAL2′-B of the 3^{rd}-2 horizontal initialization voltage line HAL2′. The first vertical bias voltage line VBL may be electrically connected to only the first horizontal bias voltage line HBL and the second portions HBL′-B of the second horizontal bias voltage line HBL′ from among the overlapping horizontal conductive lines HCL, and may be electrically isolated from the other remaining lines. This will be described in more detail below with reference to FIG. 8A.

The 2^{nd}-1 vertical initialization voltage line VAL1 may overlap with the pixel circuits PC arranged in the (c+1)^{th} column. The 2^{nd}-1 vertical initialization voltage line VAL1 may not be arranged on a straight line in the second direction (e.g., the ±y direction) with respect to the transmission area TA. Accordingly, the 2^{nd}-1 vertical initialization voltage line VAL1 may continuously extend in the second direction (e.g., the ±y direction) without being disconnected.

The 2^{nd}-1 vertical initialization voltage line VAL1 may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the second portion HBL′-B of the second horizontal bias voltage line HBL′, the second portion HIL′-B of the 1^{st}-2 horizontal initialization voltage line HIL′, the second portion HAL1′-B of the 2^{nd}-2 horizontal initialization voltage line HAL1′, and the second portion HAL2′-B of the 3^{rd}-2 horizontal initialization voltage line HAL2′. The 2^{nd}-1 vertical initialization voltage line VAL1 may be electrically connected to only the 2^{nd}-1 horizontal initialization voltage line HAL1 and the second portions HAL1′-B of the 2^{nd}-2 horizontal initialization voltage line HAL1′ from among the overlapping horizontal conductive lines HCL, and may be electrically isolated from the other remaining lines. This will be described in more detail below with reference to FIG. 8B.

The first common voltage line VSL may overlap with the pixel circuits PC arranged in the (c+2)^{th} column. The first common voltage line VSL may not be arranged on a straight line in the second direction (e.g., the ±y direction) with respect to the transmission area TA. Accordingly, the first common voltage line VSL may continuously extend in the second direction (e.g., the ±y direction) without being disconnected.

The first common voltage line VSL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the second portion HBL′-B of the second horizontal bias voltage line HBL′, the second portion HIL′-B of the 1^{st}-2 horizontal initialization voltage line HIL′, the second portion HAL1′-B of the 2^{nd}-2 horizontal initialization voltage line HAL1′, and the second portion HAL2′-B of the 3^{rd}-2 horizontal initialization voltage line HAL2′. The first common voltage line VSL may be electrically connected to the second voltage supply line (e.g., see 170 of FIG. 3), and may be electrically insulated from all of the overlapping horizontal conductive lines HCL. This will be described in more detail below with reference to FIG. 8C.

The 3^{rd}-1 vertical initialization voltage line VAL2 may overlap with the pixel circuits PC arranged in the (c+3)^{th} column. The 3^{rd}-1 vertical initialization voltage line VAL2 may not be arranged on a straight line in the second direction (e.g., the ±y direction) with respect to the transmission area TA. Accordingly, the 3^{rd}-1 vertical initialization voltage line VAL2 may continuously extend in the second direction (e.g., the ±y direction) without being disconnected.

The 3^{rd}-1 vertical initialization voltage line VAL2 may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the second portion HBL′-B of the second horizontal bias voltage line HBL′, the second portion HIL′-B of the 1^{st}-2 horizontal initialization voltage line HIL′, the second portion HAL1′-B of the 2^{nd}-2 horizontal initialization voltage line HAL1′, and the second portion HAL2′-B of the 3^{rd}-2 horizontal initialization voltage line HAL2′. The 3^{rd}-1 vertical initialization voltage line VAL2 may be electrically connected to only the 3^{rd}-1 horizontal initialization voltage line HAL2 and the second portions HAL2′-B of the 3^{rd}-2 horizontal initialization voltage line HAL2′ from among the overlapping horizontal conductive lines HCL, and may be electrically isolated from the other remaining lines. This will be described in more detail below with reference to FIG. 8D.

The 1^{st}-1 vertical initialization voltage line VIL may overlap with the pixel circuits PC arranged in the (c+4)^{th} column. The 1^{st}-1 vertical initialization voltage line VIL may not be arranged on a straight line in the second direction (e.g., the ±y direction) with respect to the transmission area TA. Accordingly, the 1^{st}-1 vertical initialization voltage line VIL may continuously extend in the second direction (e.g., the ±y direction) without being disconnected.

The 1^{st}-1 vertical initialization voltage line VIL may cross and overlap with a plurality of horizontal conductive lines HCL, for example, such as with the first horizontal bias voltage line HBL, the 1^{st}-1 horizontal initialization voltage line HIL, the 2^{nd}-1 horizontal initialization voltage line HAL1, the 3^{rd}-1 horizontal initialization voltage line HAL2, the second portion HBL′-B of the second horizontal bias voltage line HBL′, the second portion HIL′-B of the 1^{st}-2 horizontal initialization voltage line HIL′, the second portion HAL1′-B of the 2^{nd}-2 horizontal initialization voltage line HAL1′, and the second portion HAL2′-B of the 3^{rd}-2 horizontal initialization voltage line HAL2′. The 1^{st}-1 vertical initialization voltage line VIL may be electrically connected to only the 1^{st}-1 horizontal initialization voltage line HIL and the second portions HIL′-B of the 1^{st}-2 horizontal initialization voltage line HIL′ from among the overlapping horizontal conductive lines HCL, and may be electrically isolated from the other remaining lines. This will be described in more detail below with reference to FIG. 8E.

In the display panel according to one or more embodiments of the present disclosure, the first portions and the second portions of the horizontal conductive lines HCL that are spaced apart from each other with the transmission area TA therebetween may be electrically connected to each other by the vertical conductive lines VCL and the horizontal conductive lines HCL that do not overlap with the transmission area TA. Accordingly, not only when the voltage supply lines (or the voltage supply circuits) are arranged on both sides of the display panel, but also when the voltage supply line (or the voltage supply circuit) is arranged on only one side, voltages such as the bias voltage Vbias, the first initialization voltage Vint, and the second initialization voltage Vaint may be transmitted to all of the pixel circuits PC arranged in the display area DA.

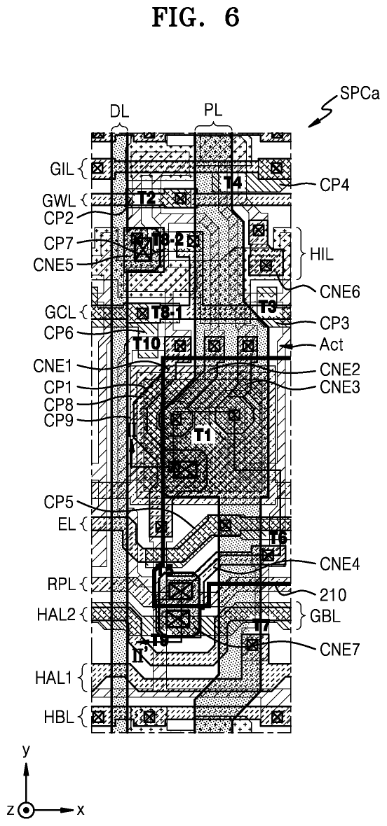

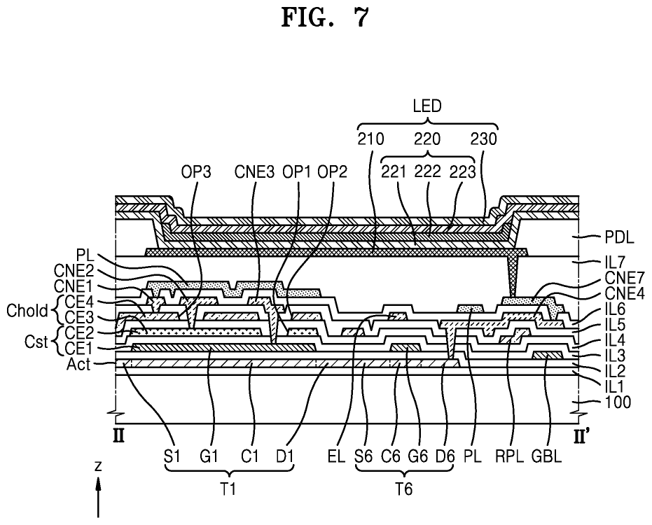

FIG. 6 is a plan view illustrating the sub-pixel on the display panel, according to an embodiment. FIG. 7 is a cross-sectional view of the display panel taken along the line II-II′ of FIG. 6. FIG. 6 illustrates an example of the first sub-pixel circuit SPCa arranged in the a^{th} row, and electrically connected to the first light-emitting diode configured to emit light of the first color (e.g., red). The first to third sub-pixel circuits SPCa, SPCb, and SPCc arranged in the display panel 10 may each have a structure that is the same or substantially the same as (or similar to) the structure of the first sub-pixel circuit SPCa illustrated in FIG. 6, and thus, redundant description thereof may not be repeated.

Referring to FIGS. 4, 6, and 7, the display panel may include a substrate 100, one or more transistors, one or more capacitors, an insulating structure including a plurality of insulating layers, and a light-emitting diode LED.

The substrate 100 may include various suitable materials, such as glass, a metal, or plastic. According to an embodiment, the substrate 100 may include a flexible material. The flexible material refers to a bendable, foldable, or rollable material. The substrate 100 including the flexible material may include ultra-thin glass, a metal, or plastic.

A first insulating layer IL1 may be disposed on the substrate 100. The first insulating layer IL1 may be a single layer or multiple layers including an inorganic insulating material, such as silicon nitride, silicon oxide, and/or silicon oxynitride.

A semiconductor layer Act may be disposed on the first insulating layer IL1. The semiconductor layer Act may include a plurality of curved portions, and first to tenth transistors T1 to T10 may be formed along the curved portions of the semiconductor layer Act. In other words, a first semiconductor of the first transistor T1, a second semiconductor of the second transistor T2, a third semiconductor of the third transistor T3, a fourth semiconductor of the fourth transistor T4, a fifth semiconductor of the fifth transistor T5, a sixth semiconductor of the sixth transistor T6, a seventh semiconductor of the seventh transistor T7, an eighth semiconductor of the eighth transistor T8, a ninth semiconductor of the ninth transistor T9, and a tenth semiconductor of the tenth transistor T10 may each correspond to a portion of the semiconductor layer Act illustrated in FIG. 6. The first to tenth semiconductors may be connected to each other to form the semiconductor layer Act illustrated in FIG. 6. The first to tenth semiconductors may each include a channel region, and a source region and a drain region on both sides (e.g., opposite sides), respectively, of the channel region. In an embodiment, the eighth transistor T8 may include an 8^{th}-1 transistor T8-1 and an 8^{th}-2 transistor T8-2.

The second insulating layer IL2 may cover the semiconductor layer Act on the first insulating layer IL1. The second insulating layer IL2 may include an inorganic insulating material, such as silicon oxide, silicon nitride, silicon oxynitride, aluminum oxide, titanium oxide, tantalum oxide, hafnium oxide, or zinc oxide.

A first conductive layer may be disposed on the second insulating layer IL2. The first conductive layer may include first to seventh conductive patterns CP1, CP2, CP3, CP4, CP5, CP6, and CP7, and a fourth scan line GBL. In other words, the first to seventh conductive patterns CP1, CP2, CP3, CP4, CP5, CP6, and CP7 and the fourth scan line GBL may be arranged at (e.g., in or on) the same layer as each other, and may include the same material as each other. The first conductive layer may include a conductive material including molybdenum (Mo), aluminum (Al), copper (Cu), titanium (Ti), and/or the like. The first conductive layer may include a single layer or multiple layers including one or more of the conductive materials described above. For example, the first to seventh conductive patterns CP1, CP2, CP3, CP4, CP5, CP6, and CP7 and the fourth scan line GBL may each have a single-layer structure of molybdenum.

A portion of the first conductive pattern CP1 may be the first gate electrode G1 of the first transistor T1. The first gate electrode G1 may be a portion overlapping with the channel region C1 of the first semiconductor, which is a portion of the semiconductor layer Act. The first semiconductor may include a source region S1 and a drain region D1 on both sides (e.g., opposite sides), respectively, of the channel region C1. The first semiconductor, which is a portion of the semiconductor layer Act, and the first gate electrode G1, which is a portion of the first conductive pattern CP1, may constitute the first transistor T1.

A portion of the first conductive pattern CP1 may be the first lower electrode CE1 of the first capacitor Cst. In other words, a portion of the first lower electrode CE1 of the first capacitor Cst may be the first gate electrode G1 of the first transistor T1.

A portion of the second conductive pattern CP2 may be the second gate electrode of the second transistor T2. The second gate electrode may be a portion that overlaps with the channel region of the second semiconductor, which is a portion of the semiconductor layer Act. The second gate electrode may be electrically connected to the first scan line GWL, and may receive the first scan signal GW from the first scan line GWL. The second semiconductor, which is a portion of the semiconductor layer Act, and the second gate electrode, which is a portion of the second conductive pattern CP2, may constitute the second transistor T2.

A portion of the third conductive pattern CP3 may be the third gate electrode of the third transistor T3. The third gate electrode may be a portion that overlaps with the channel region of the third semiconductor, which is a portion of the semiconductor layer Act. The third gate electrode may be electrically connected to the second scan line GCL, and may receive the second scan signal GC from the second scan line GCL. The third semiconductor, which is a portion of the semiconductor layer Act, and the third gate electrode, which is a portion of the third conductive pattern CP3, may constitute the third transistor T3.

A portion of the fourth conductive pattern CP4 may be the fourth gate electrode of the fourth transistor T4. The fourth gate electrode may be a portion that overlaps with the channel region of the fourth semiconductor, which is a portion of the semiconductor layer Act. The fourth gate electrode may be electrically connected to the third scan line GIL, and may receive the third scan signal GI from the third scan line GIL. The fourth semiconductor, which is a portion of the semiconductor layer Act, and the fourth gate electrode, which is a portion of the fourth conductive pattern CP4, may constitute the fourth transistor T4.

A portion of the fifth conductive pattern CP5 may be the fifth gate electrode of the fifth transistor T5, and another portion of the fifth conductive pattern CP5 may be the sixth gate electrode G6 of the sixth transistor T6. The fifth gate electrode may be a portion that overlaps with the channel region of the fifth semiconductor, which is a portion of the semiconductor layer Act. The sixth gate electrode G6 may be a portion that overlaps with the channel region C6 of the sixth semiconductor, which is a portion of the semiconductor layer Act. The sixth semiconductor may include a source region S6 and a drain region D6 on both sides (e.g., opposite sides), respectively, of the channel region C6. The fifth gate electrode and the sixth gate electrode G6 may be electrically connected to the emission control line EL, and may receive the emission control signal EM from the emission control line EL. The fifth semiconductor, which is a portion of the semiconductor layer Act, and the fifth gate electrode, which is a portion of the fifth conductive pattern CP5, may constitute the fifth transistor T5. The sixth semiconductor, which is a portion of the semiconductor layer Act, and the sixth gate electrode G6, which is a portion of the fifth conductive pattern CP5, may constitute the sixth transistor T6.

The fourth scan line GBL may extend in the first direction (e.g., the ±x direction). The fourth scan line GBL may receive the fourth scan signal GB from the scan driving circuit. A portion of the fourth scan line GBL may be the seventh gate electrode of the seventh transistor T7, and another portion of the fourth scan line GBL may be the ninth gate electrode of the ninth transistor T9. The seventh gate electrode may be a portion that overlaps with the channel region of the seventh semiconductor, which is a portion of the semiconductor layer Act. The ninth gate electrode may be a portion that overlaps with the channel region of the ninth semiconductor, which is a portion of the semiconductor layer Act. The seventh semiconductor, which is a portion of the semiconductor layer Act, and the seventh gate electrode, which is a portion of the fifth conductive pattern fourth scan line GBL, may constitute the seventh transistor T7. The ninth semiconductor, which is a portion of the semiconductor layer Act, and the ninth gate electrode, which is a portion of the fourth scan line GBL, may constitute the ninth transistor T9.

A portion of the sixth conductive pattern CP6 may be the 8^{th}-1 gate electrode of the 8^{th}-1 transistor T8-1, and another portion of the sixth conductive pattern CP6 may be the tenth gate electrode of the tenth transistor T10. The 8^{th}-1 gate electrode may be a portion that overlaps with the channel region of the 8^{th}-1 semiconductor, which is a portion of the semiconductor layer Act. The tenth gate electrode may be a portion that overlaps with the channel region of the tenth semiconductor, which is a portion of the semiconductor layer Act. The 8^{th}-1 gate electrode and the tenth gate electrode may be electrically connected to the second scan line GCL, and may receive the second scan signal GC from the second scan line GCL. The 8^{th}-1 semiconductor, which is a portion of the semiconductor layer Act, and the 8^{th}-1 gate electrode, which is a portion of the sixth conductive pattern CP6, may constitute the 8^{th}-1 transistor T8-1. The tenth semiconductor, which is a portion of the semiconductor layer Act, and the tenth gate electrode, which is a portion of the sixth conductive pattern CP6, may constitute the tenth transistor T10. For example, the sixth conductive pattern CP6 may be integrally formed with the third conductive pattern CP3 of an adjacent sub-pixel circuit.

A portion of the seventh conductive pattern CP7 may be the 8^{th}-2 gate electrode of the 8^{th}-2 transistor T8-2. The 8^{th}-2 gate electrode may be a portion that overlaps with the channel region of the 8^{th}-2 semiconductor, which is a portion of the semiconductor layer Act. The 8^{th}-2 gate electrode may be electrically connected to the second scan line GCL, and may receive the second scan signal GC from the second scan line GCL. The 8^{th}-2 semiconductor, which is a portion of the semiconductor layer Act, and the 8^{th}-2 gate electrode, which is a portion of the seventh conductive pattern CP7, may constitute the 8^{th}-2 transistor T8-2.

The third insulating layer IL3 may cover the first conductive layer on the second insulating layer IL2. The third insulating layer IL3 may include an inorganic insulating material, such as silicon oxide, silicon nitride, silicon oxynitride, aluminum oxide, titanium oxide, tantalum oxide, hafnium oxide, or zinc oxide.

A second conductive layer may be disposed on the third insulating layer IL3. The second conductive layer may include an eighth conductive pattern CP8 and the 1^{st}-1 horizontal initialization voltage line HIL. In other words, the eighth conductive pattern CP8 and the 1^{st}-1 horizontal initialization voltage line HIL may be arranged at (e.g., in or on) the same layer as each other, and may include the same material as each other. The second conductive layer may include a conductive material including molybdenum (Mo), aluminum (Al), copper (Cu), titanium (Ti), and/or the like. The second conductive layer may include a single layer or multiple layers including one or more of the conductive materials described above. In some embodiments, the second conductive layer may include a suitable material with a relatively low resistance. For example, the second conductive layer may have a multilayered structure including an aluminum layer and a titanium layer.

The eighth conductive pattern CP8 may have a first opening OP1 exposing a portion of the first conductive pattern CP1. A portion of the eighth conductive pattern CP8 may be the first upper electrode CE2 of the first capacitor Cst. In other words, a portion of the first conductive pattern CP1 and a portion of the eighth conductive pattern CP8, which overlap with each other, may constitute the first capacitor Cst. A portion of the eighth conductive pattern CP8 may be the second lower electrode CE3 of the second capacitor Chold. In other words, at least a portion of the first upper electrode CE2 of the first capacitor Cst may be the second lower electrode CE3 of the second capacitor Chold.

The 1^{st}-1 horizontal initialization voltage line HIL may extend in the first direction (e.g., the ±x direction). The 1^{st}-1 horizontal initialization voltage line HIL may receive the first initialization voltage Vint from the voltage supply circuit.

The fourth insulating layer IL4 may cover the second conductive layer on the third insulating layer IL3. The fourth insulating layer IL4 may include an inorganic insulating material, such as silicon oxide, silicon nitride, silicon oxynitride, aluminum oxide, titanium oxide, tantalum oxide, hafnium oxide, or zinc oxide.

A third conductive layer may be disposed on the fourth insulating layer IL4. The third conductive layer may include a ninth conductive pattern CP9 and a repair line RPL. In other words, the ninth conductive pattern CP9 and the repair line RPL may be arranged at (e.g., in or on) the same layer as each other, and may include the same material as each other. The third conductive layer may include a conductive material including molybdenum (Mo), aluminum (Al), copper (Cu), titanium (Ti), and/or the like, and may include a single layer or multiple layers including one or more of the conductive materials described above. For example, the third conductive layer may have a multilayered structure including an aluminum layer and a titanium layer.

The ninth conductive pattern CP9 may have a second opening OP2 and a third opening OP3, which are spaced apart from each other. The second opening OP2 of the ninth conductive pattern CP9 may overlap with the first opening OP1 of the eighth conductive pattern CP8. The first opening OP1 of the eighth conductive pattern CP8 and the second opening OP2 of the ninth conductive pattern CP9 may expose a portion of the first conductive pattern CP1. The third opening OP3 of the ninth conductive pattern CP9 may expose a portion of the eighth conductive pattern CP8. A portion of the ninth conductive pattern CP9 may be the second upper electrode CE4 of the second capacitor Chold. In other words, a portion of the eighth conductive pattern CP8 and a portion of the ninth conductive pattern CP9, which overlap with each other, may constitute the second capacitor Chold.

The repair line RPL may extend in the first direction (e.g., the ±x direction).

The fifth insulating layer IL5 may cover the third conductive layer on the fourth insulating layer IL4. The fifth insulating layer IL5 may include an inorganic insulating material, such as silicon oxide, silicon nitride, silicon oxynitride, aluminum oxide, titanium oxide, tantalum oxide, hafnium oxide, or zinc oxide.

A fourth conductive layer may be disposed on the fifth insulating layer IL5. The fourth conductive layer may include first to sixth connection electrodes CNE1, CNE2, CNE3, CNE4, CNE5, and CNE6, the first to third scan lines GWL, GCL, and GIL, the emission control line EL, the first horizontal bias voltage line HBL, the 2^{nd}-1 horizontal initialization voltage line HAL1, and the 3^{rd}-1 horizontal initialization voltage line HAL2. In other words, the first to sixth connection electrodes CNE1, CNE2, CNE3, CNE4, CNE5, and CNE6, the first to third scan lines GWL, GCL, and GIL, the emission control line EL, the first horizontal bias voltage line HBL, the 2^{nd}-1 horizontal initialization voltage line HAL1, and the 3^{rd}-1 horizontal initialization voltage line HAL2 may be arranged at (e.g., in or on) the same layer as each other, and may include the same material as each other. The fourth conductive layer may include a conductive material including aluminum (Al), copper (Cu), titanium (Ti), and/or the like, and may include a single layer or multiple layers including one or more of the conductive materials described above. For example, the first to sixth connection electrodes CNE1, CNE2, CNE3, CNE4, CNE5, and CNE6, the first to third scan lines GWL, GCL, and GIL, the emission control line EL, the first horizontal bias voltage line HBL, the 2^{nd}-1 horizontal initialization voltage line HAL1, and the 3^{rd}-1 horizontal initialization voltage line HAL2 may each include a three-layered structure including a titanium layer, an aluminum layer, and a titanium layer.

The first connection electrode CNE1 may be electrically connected to the source region of the fifth semiconductor of the fifth transistor T5, which is a portion of the semiconductor layer Act, the source region of the 8^{th}-1 semiconductor of the 8^{th}-1 transistor T8-1, the source region of the tenth semiconductor of the tenth transistor T10, and the ninth conductive pattern CP9 through contact holes formed in the lower insulating layer.

The second connection electrode CNE2 may be electrically connected to the drain region of the second semiconductor of the second transistor T2, which is a portion of the semiconductor layer Act, and a portion of the eighth conductive pattern CP8, which is exposed by the third opening OP3 of the ninth conductive pattern CP9, through contact holes formed in the lower insulating layer. Accordingly, the second connection electrode CNE2 may electrically connect the drain electrode of the second transistor T2 to the first upper electrode CE2 of the first capacitor Cst, and may electrically connect the drain electrode of the second transistor T2 to the second lower electrode CE3 of the second capacitor Chold.

The third connection electrode CNE3 may be electrically connected to the drain region of the third semiconductor of the third transistor T3, which is a portion of the semiconductor layer Act, and a portion of the first conductive pattern CP1, which is exposed by the second opening OP2 of the ninth conductive pattern CP9 and the first opening OP1 of the eighth conductive pattern CP8, through contact holes formed in the lower insulating layer. Accordingly, the third connection electrode CNE3 may electrically connect the first lower electrode CE1 of the first capacitor Cst to the drain electrode of the third transistor T3.

The fourth connection electrode CNE4 may be electrically connected to the drain region D6 of the sixth semiconductor of the sixth transistor T6 and the drain region of the seventh semiconductor of the seventh transistor T7, which are portions of the semiconductor layer Act, through contact holes formed in the lower insulating layer.

The fifth connection electrode CNE5 may be electrically connected to the source region of the second semiconductor of the second transistor T2, which is a portion of the semiconductor layer Act, through a contact hole formed in the lower insulating layer.

The sixth connection electrode CNE6 may be electrically connected to the source region of the fourth semiconductor of the fourth transistor T4, which is a portion of the semiconductor layer Act, and the 1^{st}-1 horizontal initialization voltage line HIL through contact holes formed in the lower insulating layer. Accordingly, the first initialization voltage Vint may be transmitted to the source region of the fourth transistor T4.

The first scan line GWL may extend in the first direction (e.g., the ±x direction). The first scan line GWL may receive the first scan signal GW from the scan driving circuit. The first scan line GWL may be electrically connected to the second conductive pattern CP2 through a contact hole formed in the lower insulating layer. Accordingly, the first scan signal GW may be transmitted to the second gate electrode of the second transistor T2.

The second scan line GCL may extend in the first direction (e.g., the ±x direction). The second scan line GCL may receive the second scan signal GC from the scan driving circuit. The second scan line GCL may be electrically connected to the sixth conductive pattern CP6 and the seventh conductive pattern CP7 through contact holes formed in the lower insulating layer. Accordingly, the second scan signal GC may be transmitted to the 8^{th}-1 gate electrode of the 8^{th}-1 transistor T8-1, the 8^{th}-2 gate electrode of the 8^{th}-2 transistor T8-2, and the tenth gate electrode of the tenth transistor T10.

The third scan line GIL may extend in the first direction (e.g., the ±x direction). The third scan line GIL may receive the third scan signal GI from the scan driving circuit. The third scan line GIL may be electrically connected to the fourth conductive pattern CP4 through a contact hole formed in the lower insulating layer. Accordingly, the third scan signal GI may be transmitted to the fourth gate electrode of the fourth transistor T4.

The emission control line EL may extend in the first direction (e.g., the ±x direction). The emission control line EL may receive the emission control signal EM from the emission control driving circuit. The emission control line EL may be electrically connected to the fifth conductive pattern CP5 through a contact hole formed in the lower insulating layer. Accordingly, the emission control signal EM may be transmitted to the fifth gate electrode of the fifth transistor T5 and the sixth gate electrode G6 of the sixth transistor T6.

The first horizontal bias voltage line HBL may extend in the first direction (e.g., the ±x direction). The first horizontal bias voltage line HBL may receive the bias voltage Vbias from the voltage supply circuit. The first horizontal bias voltage line HBL may be electrically connected to the source region of the ninth semiconductor of the ninth transistor T9, which is a portion of the semiconductor layer Act, through a contact hole formed in the lower insulating layer. Accordingly, the bias voltage Vbias may be transmitted to the source electrode of the ninth transistor T9.

The 2^{nd}-1 horizontal initialization voltage line HAL1 may extend in the first direction (e.g., the ±x direction). The 2^{nd}-1 horizontal initialization voltage line HAL1 may receive the second initialization voltage Vaint from the voltage supply circuit. In the first sub-pixel circuit SPCa and the third sub-pixel circuit SPCc, the 2^{nd}-1 horizontal initialization voltage line HAL1 may be electrically connected to the source region of the seventh semiconductor of the seventh transistor T7, which is a portion of the semiconductor layer Act, through a contact hole formed in the lower insulating layer. Accordingly, the second initialization voltage Vaint may be transmitted to the source electrode of the seventh transistor T7. In the second sub-pixel circuit SPCb, the 2^{nd}-1 horizontal initialization voltage line HAL1 may not be electrically connected to lower layers.

The 3^{rd}-1 horizontal initialization voltage line HAL2 may extend in the first direction (e.g., the ±x direction). The 3^{rd}-1 horizontal initialization voltage line HAL2 may receive the second initialization voltage Vaint from the voltage supply circuit. In the first sub-pixel circuit SPCa and the third sub-pixel circuit SPCC, the 3^{rd}-1 horizontal initialization voltage line HAL2 may not be electrically connected to lower layers. In the second sub-pixel circuit SPCb, the 3^{rd}-1 horizontal initialization voltage line HAL2 may be electrically connected to the source region of the seventh semiconductor of the seventh transistor T7, which is a portion of the semiconductor layer Act, through a contact hole formed in the lower insulating layer. Accordingly, the second initialization voltage Vaint may be transmitted to the source electrode of the seventh transistor T7.

The sixth insulating layer IL6 may cover the fourth conductive layer on the fifth insulating layer IL5. The sixth insulating layer IL6 may include an inorganic insulating material, such as silicon oxide, silicon nitride, silicon oxynitride, aluminum oxide, titanium oxide, tantalum oxide, hafnium oxide, or zinc oxide.

A fifth conductive layer may be disposed on the sixth insulating layer IL6. The fifth conductive layer may include the data line DL, the driving voltage line PL, and a seventh connection electrode CNE7. In other words, the data line DL, the driving voltage line PL, and the seventh connection electrode CNE7 may be disposed at (e.g., in or on) the same layer as each other, and may include the same material as each other. The fifth conductive layer may include a conductive material including aluminum (Al), copper (Cu), titanium (Ti), and/or the like, and may include a single layer or multiple layers including one or more of the conductive materials described above. For example, the data line DL, the driving voltage line PL, and the seventh connection electrode CNE7 may each include a three-layered structure including a titanium layer, an aluminum layer, and a titanium layer.

The data line DL may extend in the second direction (e.g., the ±y direction). The data line DL may receive the data voltage Dm from the data driving circuit. The data line DL may be electrically connected to the fifth connection electrode CNE5 through a contact hole formed in the lower insulating layer. Accordingly, the data voltage Dm may be transmitted to the source electrode of the second transistor T2 through the fifth connection electrode CNE5.

The driving voltage line PL may extend in the second direction (e.g., the ±y direction). The driving voltage line PL may receive the first power supply voltage ELVDD from the first voltage supply line 160. The driving voltage line PL may be electrically connected to the first connection electrode CNE1 through a contact hole formed in the lower insulating layer. Accordingly, the first power supply voltage ELVDD may be transmitted through the first connection electrode CNE1 to the source electrode of the fifth transistor T5, the source electrode of the 8^{th}-1 transistor T8-1, the source electrode of the tenth transistor T10, and the second upper electrode CE4 of the second capacitor Chold.

The seventh connection electrode CNE7 may be electrically connected to the fourth connection electrode CNE4 through a contact hole formed in the lower insulating layer.

The seventh insulating layer IL7 may cover the fifth conductive layer on the sixth insulating layer IL6. The seventh insulating layer IL7 may include a general-purpose polymer (e.g., benzocyclobutene (BCB), polyimide, hexamethyldisiloxane (HMDSO), polymethylmethacrylate (PMMA), or polystylene (PS)), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or any suitable blend thereof.

A pixel electrode 210 may be disposed on the seventh insulating layer IL7. In some embodiments, the pixel electrode 210 may include a reflective layer, and a transparent or semitransparent electrode layer disposed on the reflective layer. The reflective layer may include Ag, Mg, Al, Pt, Pd, Au, Ni, Nd, Ir, Cr, or any suitable compound thereof. The transparent or semitransparent electrode layer may include at least one selected from among indium tin oxide (ITO), indium zinc oxide (IZO), zinc oxide (ZnO), indium oxide (In2O3), indium gallium oxide (IGO), and/or aluminum zinc oxide (AZO). In some embodiments, the pixel electrode 210 may have a stacked structure of ITO/Ag/ITO.

The pixel electrode 210 may be electrically connected to the seventh connection electrode CNE7 through a contact hole formed in the lower insulating layer. Accordingly, the pixel electrode 210 may be electrically connected to the drain electrode of the sixth transistor T6 and the drain electrode of the seventh transistor T7 through the seventh connection electrode CNE7 and the fourth connection electrode CNE4.

A pixel defining layer PDL may be disposed on the seventh insulating layer IL7. The pixel defining layer PDL may have a pixel opening exposing at least a portion of the pixel electrode 210. The pixel defining layer PDL may include at least one organic insulating material selected from among polyimide, polyamide, acrylic resin, BCB, and/or phenol resin. In some embodiments, the pixel defining layer PDL including an inorganic insulating material, such as silicon nitride, silicon oxide, and/or silicon oxynitride, may be disposed.

At least a portion of an intermediate layer 220 may be disposed within the pixel opening of the pixel defining layer PDL. The intermediate layer 220 may include a first functional layer 221 disposed below an emission layer 222 and/or a second functional layer 223 disposed above the emission layer 222. The first functional layer 221 may include a hole transport layer (HTL) and/or a hole injection layer (HIL). The emission layer 222 may include a high molecular weight organic material or a low molecular weight organic material that emits light of a desired color (e.g., a certain or predetermined color). The second functional layer 223 may include an electron transport layer (ETL) and/or an electron injection layer (EIL). The first functional layer 221 and the second functional layer 223 may each include an organic material.

An opposite electrode 230 may be a transmissive electrode or a reflective electrode. In some embodiments, the opposite electrode 230 may be a transparent or semitransparent electrode, and may include a metal thin-film having a low work function, such as Li, Ca, LiF/Ca, LiF/Al, Al, Ag, Mg, and/or any suitable compound thereof. In addition, a transparent conductive oxide (TCO) layer, such as ITO, IZO, ZnO, or In2O3, may be further disposed on the metal thin-film. The pixel electrode 210, the intermediate layer 220, and the opposite electrode 230 may constitute the light-emitting diode LED.

The light-emitting diode LED may be covered with an encapsulation layer including at least one organic encapsulation layer and at least one inorganic encapsulation layer. Although the structure and arrangement relationship of the sub-pixel circuit SPC and the lines have been described above with reference to FIGS. 4, 6, and 7, the present disclosure is not limited thereto, and the structure and arrangement relationship may be variously modified as needed or desired.

FIGS. 8A through 8E are plan views schematically illustrating the pixel circuits that are adjacent to one another in FIG. 5, and the horizontal and vertical conductive lines overlapping with the pixel circuits. FIG. 8A illustrates the horizontal conductive lines HCL and the vertical conductive lines VCL overlapping with the pixel circuit PC arranged in the a^{th} column. FIG. 8B illustrates the horizontal conductive lines HCL and the vertical conductive lines VCL overlapping with the pixel circuit PC arranged in the (a+1)^{th} column. FIG. 8C illustrates the horizontal conductive lines HCL and the vertical conductive lines VCL overlapping with the pixel circuit PC arranged in the (a+2)^{th} column. FIG. 8D illustrates the horizontal conductive lines HCL and the vertical conductive lines VCL overlapping with the pixel circuit PC arranged in the (a+3)^{th} column. FIG. 8E illustrates the horizontal conductive lines HCL and the vertical conductive lines VCL overlapping with the pixel circuit PC arranged in the (a+4)^{th} column.

Referring to FIGS. 5, 8A, 8B, 8C, 8D, and 8E, the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2 may extend in the first direction (e.g., the ±x direction) so as to overlap with the pixel circuits PC arranged in the a^{th} row.

The first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may each extend in the second direction (e.g., the ±y direction). For example, the first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may each be located between the second sub-pixel circuit SPCb and the third sub-pixel circuit SPCc.

The first vertical bias voltage line VBL may overlap with the pixel circuit PC arranged in the a^{th} column (e.g., see FIG. 8A). The 2^{nd}-1 vertical initialization voltage line VAL1 may overlap with the pixel circuit PC arranged in the (a+1)^{th} column (e.g., see FIG. 8B). The first common voltage line VSL may overlap with the pixel circuit PC arranged in the (a+2)^{th} column (e.g., see FIG. 8C). The 3^{rd}-1 vertical initialization voltage line VAL2 may overlap with the pixel circuit PC arranged in the (a+3)^{th} column (e.g., see FIG. 8D). The 1^{st}-1 vertical initialization voltage line VIL may overlap with the pixel circuit PC arranged in the (a+4)^{th} column (e.g., see FIG. 8E).

In an embodiment, the first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may be arranged at (e.g., in or on) the same layer as each other. The first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may be disposed at (e.g., in or on) different layers from those of the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. For example, the first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may be arranged at (e.g., in or on) the same layer as that of the data line DL and the driving voltage line PL illustrated in FIGS. 6 and 7, and may include the same material as each other. For example, the sixth insulating layer IL6 may be located between the first horizontal bias voltage line HBL and the first vertical bias voltage line VBL, the first horizontal bias voltage line HBL may be disposed below the sixth insulating layer IL6, and the first vertical bias voltage line VBL may be disposed above the sixth insulating layer IL6.

The first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may overlap with the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2. For example, the first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL may include a first protrusion PP1 overlapping with the first horizontal bias voltage line HBL, a second protrusion PP2 overlapping with the 1^{st}-1 horizontal initialization voltage line HIL, a third protrusion PP3 overlapping with the 2^{nd}-1 horizontal initialization voltage line HAL1, and a fourth protrusion PP4 overlapping with the 3^{rd}-1 horizontal initialization voltage line HAL2. For example, the first to fourth protrusions PP1, PP2, PP3, and PP4 may each have a relatively larger width (e.g., a width in the ±x direction).

The first vertical bias voltage line VBL may be electrically connected to only the first horizontal bias voltage line HBL from among the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, each overlapping with the first vertical bias voltage line VBL. For example, as illustrated in FIG. 8A, a contact hole CNTa may be disposed directly below the first protrusion PP1 of the first vertical bias voltage line VBL. Accordingly, the first vertical bias voltage line VBL may be electrically connected to the first horizontal bias voltage line HBL through the contact hole CNTa. A contact hole may not be located directly below each of the second, third, and fourth protrusions PP2, PP3, and PP4 of the first vertical bias voltage line VBL. Accordingly, the first vertical bias voltage line VBL may be electrically isolated from the 1^{st}-1 horizontal initialization voltage line HIL, the 2^{nd}-1 horizontal initialization voltage line HAL1, and the 3^{rd}-1 horizontal initialization voltage line HAL2.

The 2^{nd}-1 vertical initialization voltage line VAL1 may be electrically connected to only the 2^{nd}-1 horizontal initialization voltage line HAL1 from among the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, each overlapping with the 2^{nd}-1 vertical initialization voltage line VAL1. For example, as illustrated in FIG. 8B, a contact hole CNTb may be disposed directly below the third protrusion PP3 of the 2^{nd}-1 vertical initialization voltage line VAL1. Accordingly, the 2^{nd}-1 vertical initialization voltage line VAL1 may be electrically connected to the 2^{nd}-1 horizontal initialization voltage line HAL1 through the contact hole CNTb. A contact hole may not be located directly below each of the first, second, and fourth protrusions PP1, PP2, and PP4 of the 2^{nd}-1 vertical initialization voltage line VAL1. Accordingly, the 2^{nd}-1 vertical initialization voltage line VAL1 may be electrically isolated from the first horizontal bias voltage line HBL, the 1^{st}-1 horizontal initialization voltage line HIL, and the 3^{rd}-1 horizontal initialization voltage line HAL2.

The first common voltage line VSL may be electrically isolated from all of the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, each overlapping with the first common voltage line VSL. For example, as illustrated in FIG. 8C, a contact hole may not be located directly below each of the first, second, third, and fourth protrusions PP1, PP2, PP3, and PP4 of the first common voltage line VSL.

The 3^{rd}-1 vertical initialization voltage line VAL2 may be electrically connected to only the 3^{rd}-1 horizontal initialization voltage line HAL2 from among the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, each overlapping with the 3^{rd}-1 vertical initialization voltage line VAL2. For example, as illustrated in FIG. 8D, a contact hole CNTc may be disposed directly below the fourth protrusion PP4 of the 3^{rd}-1 vertical initialization voltage line VAL2. Accordingly, the 3^{rd}-1 vertical initialization voltage line VAL2 may be electrically connected to the 3^{rd}-1 horizontal initialization voltage line HAL2 through the contact hole CNTc. A contact hole may not be located directly below each of the first, second, and third protrusions PP1, PP2, and PP3 of the 3^{rd}-1 vertical initialization voltage line VAL2. Accordingly, the 3^{rd}-1 vertical initialization voltage line VAL2 may be electrically isolated from the first horizontal bias voltage line HBL, the 1^{st}-1 horizontal initialization voltage line HIL, and the 2^{nd}-1 horizontal initialization voltage line HAL1.

The 1^{st}-1 vertical initialization voltage line VIL may be electrically connected to only the 1^{st}-1 horizontal initialization voltage line HIL from among the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, each overlapping with the 1^{st}-1 vertical initialization voltage line VIL. For example, as illustrated in FIG. 8E, a contact hole CNTd may be disposed directly below the second protrusion PP2 of the 1^{st}-1 vertical initialization voltage line VIL. Accordingly, the 1^{st}-1 vertical initialization voltage line VIL may be electrically connected to the sixth connection electrode CNE6 and the 1^{st}-1 horizontal initialization voltage line HIL through the contact hole CNTd. A contact hole may not be located directly below each of the first, third, and fourth protrusions PP1, PP3, and PP4 of the 1^{st}-1 vertical initialization voltage line VIL. Accordingly, the 1^{st}-1 vertical initialization voltage line VIL may be electrically isolated from the first horizontal bias voltage line HBL, the 2^{nd}-1 horizontal initialization voltage line HAL1, and the 3^{rd}-1 horizontal initialization voltage line HAL2.

The structure and arrangement relationship of the first sub-pixel circuit SPCa arranged in the a^{th} row and the lines overlapping with the first sub-pixel circuit SPCa described above with reference to FIGS. 5 to 8E may be applied to the first to third sub-pixel circuits SPCa, SPCb, and SPCc and the lines arranged in the display area DA in the same or substantially the same (or similar) manner. For example, the second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′ may have the same or substantially the same structures and arrangement relationships as those of the first horizontal bias voltage line HBL, the 1^{st}-1 horizontal initialization voltage line HIL, the 2^{nd}-1 horizontal initialization voltage line HAL1, and the 3^{rd}-1 horizontal initialization voltage line HAL2, respectively. Similarly, the second vertical bias voltage line VBL′, the 1^{st}-2 vertical initialization voltage line VIL′, the 2^{nd}-2 vertical initialization voltage line VAL1′, the 3^{rd}-2 vertical initialization voltage line VAL2′, and the second common voltage line VSL′ may have the same or substantially the same structures and arrangement relationships as those of the first vertical bias voltage line VBL, the 1^{st}-1 vertical initialization voltage line VIL, the 2^{nd}-1 vertical initialization voltage line VAL1, the 3^{rd}-1 vertical initialization voltage line VAL2, and the first common voltage line VSL, respectively.

For example, the first vertical bias voltage line VBL may include a first protrusion PP1 overlapping with the first portion (e.g., see HBL′-A of FIG. 5) of the second horizontal bias voltage line (e.g., see HBL′ of FIG. 5), a second protrusion PP2 overlapping with the first portion (e.g., see HIL′-A of FIG. 5) of the 1^{st}-2 horizontal initialization voltage line (e.g., see HIL′ of FIG. 5), a third protrusion PP3 overlapping with the first portion (e.g., see HAL1′-A of FIG. 5) of the 2^{nd}-2 horizontal initialization voltage line (e.g., see HAL1′ of FIG. 5), and a fourth protrusion PP4 overlapping with the first portion (e.g., see HAL2′-A of FIG. 5) of the 3^{rd}-2 horizontal initialization voltage line (e.g., see HAL2′ of FIG. 5).

According to one or more embodiments of the present disclosure, vertical conductive lines VCL may be respectively electrically connected to the horizontal conductive lines HCL configured to transmit various voltages to the sub-pixel circuits SPC. The vertical conductive lines VCL may prevent or substantially prevent voltage drops of voltages (e.g., the bias voltage Vbias, the first initialization voltage Vint, the second initialization voltage Vaint, and/or the like) that may occur as the area of the display area DA is increased. Accordingly, the display quality of the display panel 10 may be improved. In addition, even when the display panel 10 includes the first through hole 10H located in the transmission area TA, as illustrated in FIG. 2A, a separate auxiliary voltage line (e.g., a routing line) may not be formed in the first non-display area NDA1 surrounding (e.g., around a periphery of) the transmission area TA. Therefore, a dead space around (e.g., adjacent to) the transmission area TA may be reduced. In addition, even when the display panel 10 does not include a through hole, as illustrated in FIG. 2B, the number of lines arranged in the transmission area TA may be reduced. For example, the horizontal conductive lines HCL arranged on a straight line in the first direction (e.g., the ±x direction) with respect to the transmission area TA may be disconnected around (e.g., adjacent to) the transmission area TA. For example, the vertical conductive lines VCL arranged on a straight line in the second direction (e.g., the ±y direction) with respect to the transmission area TA may be disconnected around (e.g., adjacent to) the transmission area TA. Accordingly, by increasing the transmittance of the transmission area TA, a deterioration in the function of the component arranged in the transmission area TA (e.g., a deterioration in the image quality of the camera disposed on the back surface of the display panel 10) may be prevented or substantially prevented.

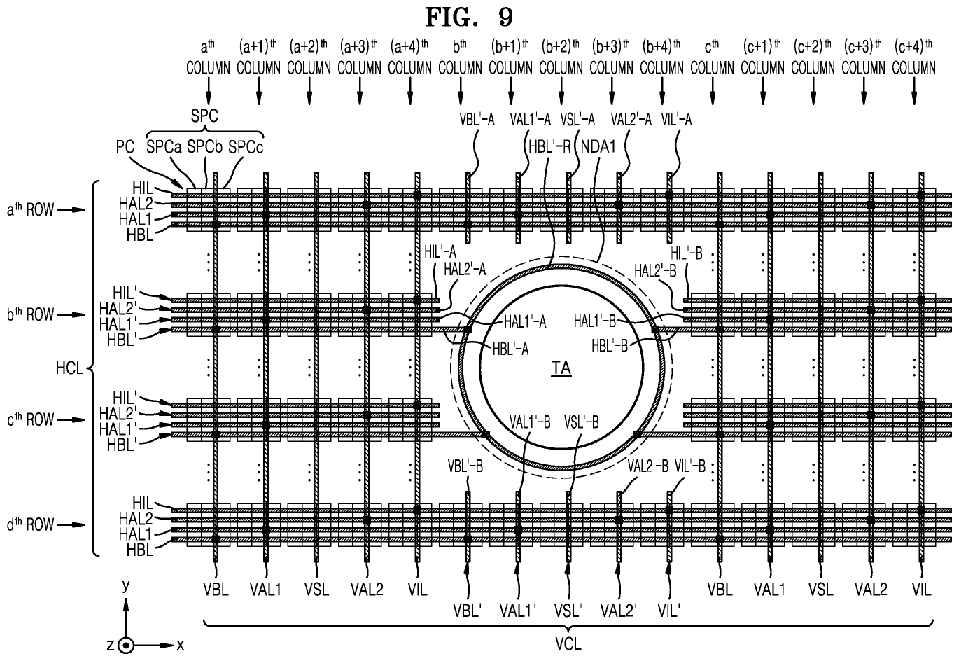

FIG. 9 is a plan view schematically illustrating pixel circuits and lines on a display panel 10, according to an embodiment.

Referring to FIG. 9, the display panel 10 may further include an auxiliary voltage line HBL′-R arranged in the first non-display area NDA1. Hereinafter, for convenience, the differences in FIG. 9 from those described above with reference to FIG. 5 may be mainly described, and redundant description may not be repeated.

The auxiliary voltage line HBL′-R may be arranged in the first non-display area NDA1 surrounding (e.g., around a periphery of) the transmission area TA. For example, the auxiliary voltage line HBL′-R may have a ring shape extending in the circumferential direction of the transmission area TA. However, the shape of the auxiliary voltage line HBL′-R is not limited to the shape illustrated in FIG. 9, and the auxiliary voltage line HBL′-R may have a discontinuous shape instead of the illustrated continuous ring shape. In addition, the auxiliary voltage line HBL′-R may have various suitable shapes, such as various different polygonal shapes.

The auxiliary voltage line HBL′-R may be electrically connected to some of the horizontal conductive lines HCL arranged on a straight line in the first direction (e.g., the ±x direction) with respect to the transmission area TA, and/or some of the vertical conductive lines VCL arranged on a straight line in the second direction (e.g., the ±y direction) with respect to the transmission area TA.

In an embodiment, the auxiliary voltage line HBL′-R may be electrically connected to some of the horizontal conductive lines HCL arranged on a straight line in the first direction (e.g., the ±x direction) with respect to the transmission area TA, for example, such as to the second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′. For example, the auxiliary voltage line HBL′-R may be electrically connected to the second horizontal bias voltage line HBL′, and may be electrically isolated from the 1^{st}-2 horizontal initialization voltage line HIL′, the 2^{nd}-2 horizontal initialization voltage line HAL1′, and the 3^{rd}-2 horizontal initialization voltage line HAL2′. In an embodiment, the auxiliary voltage line HBL′-R may be arranged at (e.g., in or on) a different layer from that of the second horizontal bias voltage line HBL′, and may connect the first portion HBL′-A and the second portion HBL′-B of the second horizontal bias voltage line HBL′, which are spaced apart from each other around the transmission area TA, to each other through contact holes. In another embodiment, the auxiliary voltage line HBL′-R may be arranged at (e.g., in or on) the same layer as that of the second horizontal bias voltage line HBL′. In an embodiment, the second horizontal bias voltage lines HBL′ may be electrically connected to the auxiliary voltage line HBL′-R. For example, the first portions HBL′-A and the second portions HBL′-B included in the second horizontal bias voltage lines HBL′ overlapping with the b^{th} and c^{th} rows may be electrically connected to the auxiliary voltage line HBL′-R through contact holes.

For example, the auxiliary voltage line HBL′-R may include a suitable material having a resistivity lower than a resistivity of the second horizontal bias voltage line HBL′. The width of the auxiliary voltage line HBL′-R may be different from the width of the second horizontal bias voltage line HBL′. For example, the width of the auxiliary voltage line HBL′-R may be greater than the width of the second horizontal bias voltage line HBL′.

In an embodiment, the auxiliary voltage line HBL′-R may be electrically connected to some of the vertical conductive lines VCL arranged on a straight line in the second direction (e.g., the ±y direction) with respect to the transmission area TA, for example, such as to the second vertical bias voltage line VBL′, the 1^{st}-2 vertical initialization voltage line VIL′, the 2^{nd}-2 vertical initialization voltage line VAL1′, and the 3^{rd}-2 vertical initialization voltage line VAL2′. For example, the auxiliary voltage line HBL′-R may be electrically connected to the second vertical bias voltage line VBL′, and may be electrically isolated from the 1^{st}-2 vertical initialization voltage line VIL′, the 2^{nd}-2 vertical initialization voltage line VAL1′, and the 3^{rd}-2 vertical initialization voltage line VAL2′. In an embodiment, the auxiliary voltage line HBL′-R may be arranged at (e.g., in or on) a different layer from that of the second vertical bias voltage line VBL′, and may connect the portions (e.g., the first portion VBL′-A and the second portion VBL′-B) of the second vertical bias voltage line VBL′, which are spaced apart from each other around the transmission area TA, to each other through contact holes. In another embodiment, the auxiliary voltage line HBL′-R may be arranged at (e.g., in or on) the same layer as that of the second vertical bias voltage line VBL′.

For example, the auxiliary voltage line HBL′-R may include a suitable material having a resistivity lower than a resistivity of the second vertical bias voltage line VBL′. The width of the auxiliary voltage line HBL′-R may be different from the width of the second vertical bias voltage line VBL′. For example, the width of the auxiliary voltage line HBL′-R may be greater than the width of the second vertical bias voltage line VBL′.

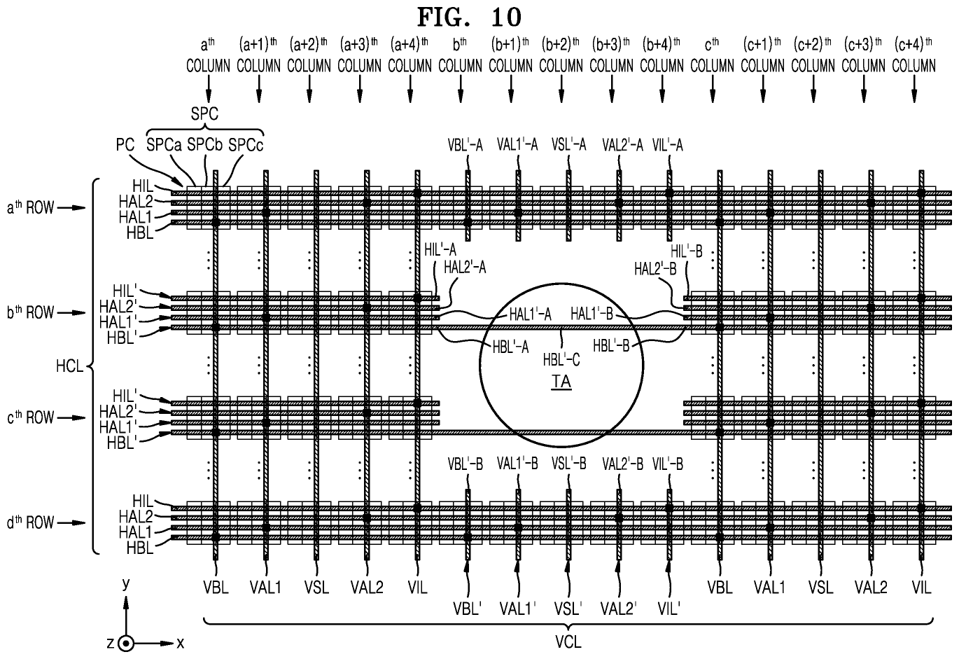

FIG. 10 is a plan view schematically illustrating pixel circuits and lines on a display panel 10, according to an embodiment.

The display panel 10 illustrated in FIG. 10 may be a display panel 10 that does not include a through hole in the transmission area TA, as illustrated in FIG. 2B. For example, a sub-display area in which display elements are arranged and a transmission portion with high transmittance without display elements may be repeatedly arranged in the transmission area TA. Accordingly, the transmission area TA may secure a transmittance. In addition, the first non-display area NDA1 around (e.g., adjacent to) the transmission area TA may be omitted.

Referring to FIG. 10, some of the horizontal conductive lines HCL arranged on a straight line in the first direction (e.g., the ±x direction) with respect to the transmission area TA and/or some of the vertical conductive lines VCL arranged on a straight line in the second direction (e.g., the ±y direction) with respect to the transmission area TA may continuously extend across the transmission area TA without being disconnected.

In an embodiment, some of the horizontal conductive lines HCL arranged on a straight line in the first direction (e.g., the ±x direction) with respect to the transmission area TA, for example, such as the second horizontal bias voltage line HBL′, the 1^{st}-2 horizontal initialization voltage line HIL′, the 2^{nd}-2 horizontal initialization voltage line HAL1′, and the 3^{rd}-2 horizontal initialization voltage line HAL2′, may not be disconnected and may continuously extend in the first direction (e.g., the ±x direction) across the transmission area TA. In other words, some of the horizontal conductive lines HCL arranged on a straight line in the first direction (e.g., the ±x direction) with respect to the transmission area TA may overlap with the transmission area TA. For example, the second horizontal bias voltage line HBL′ may not be disconnected around (e.g., adjacent to) the transmission area TA, and the 1^{st}-2 horizontal initialization voltage line HIL′, the 2^{nd}-2 horizontal initialization voltage line HAL1′, and the 3^{rd}-2 horizontal initialization voltage line HAL2′ may each be disconnected around (e.g., adjacent to) the transmission area TA.

The second horizontal bias voltage line HBL′ may further include a third portion HBL′-C connecting the first portion HBL′-A and the second portion HBL′-B, which are spaced apart from each other around the transmission area TA, to each other. The third portion HBL′-C may be a portion overlapping with the transmission area TA in the z direction. The third portion HBL′-C may extend in the first direction (e.g., the ±x direction) across the transmission area TA. In an embodiment, the first to third portions HBL′-A, HBL′-B, and HBL′-C of the second horizontal bias voltage line HBL′ may be integrally formed with each other as a single body. In other words, the second horizontal bias voltage line HBL′ may not be disconnected around the transmission area TA, and may continuously extend in the first direction (e.g., the ±x direction) across the transmission area TA. In another embodiment, the third portion HBL′-C of the second horizontal bias voltage line HBL′ may connect the first portion HBL′-A to the second portion HBL′-B, and may be arranged at (e.g., in or on) a different layer from that of the first portion HBL′-A and the second portion HBL′-B.

In an embodiment, some of the vertical conductive lines VCL arranged on a straight line in the second direction (e.g., the ±y direction) with respect to the transmission area TA, for example, such as the second vertical bias voltage line VBL′, the 1^{st}-2 vertical initialization voltage line VIL′, the 2^{nd}-2 vertical initialization voltage line VAL1′, and the 3^{rd}-2 vertical initialization voltage line VAL2′, may not be disconnected and may continuously extend in the second direction (e.g., the ±y direction) across the transmission area TA. In other words, some of the vertical conductive lines VCL arranged on a straight line in the second direction (e.g., the ±y direction) with respect to the transmission area TA may overlap with the transmission area TA. For example, the second vertical bias voltage line VBL′ may not be disconnected around (e.g., adjacent to) the transmission area TA, and the 1^{st}-2 vertical initialization voltage line VIL′, the 2^{nd}-2 vertical initialization voltage line VAL1′, and the 3^{rd}-2 vertical initialization voltage line VAL2′ may each be disconnected around (e.g., adjacent to) the transmission area TA. For example, the second vertical bias voltage line VBL′ may further include a third portion connecting the first portion VBL′-A and the second portion VBL′-B, which are spaced apart from each other around the transmission area TA, to each other.

According to one or more embodiments of the present disclosure, a display panel having improved display quality may be provided. However, the aspects and features of the present disclosure are not limited to those described above.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display panel comprising:
a substrate comprising:
a transmission area; and
a display area surrounding the transmission area;
a plurality of pixel circuits in the display area, and comprising:
a first pixel circuit; and
a second pixel circuit at a same row as that of the first pixel circuit, and spaced from the first pixel circuit in a first direction with the transmission area therebetween;
a first horizontal conductive line extending in the first direction, and spaced from the transmission area in a second direction crossing the first direction;
a second horizontal conductive line comprising:
a first portion extending in the first direction, and overlapping with the first pixel circuit; and
a second portion extending in the first direction, spaced from the first portion with the transmission area therebetween, and overlapping with the second pixel circuit;
a first vertical conductive line extending in the second direction, overlapping with the first pixel circuit, and electrically connected to the first horizontal conductive line and the first portion of the second horizontal conductive line; and
a second vertical conductive line extending in the second direction, overlapping with the second pixel circuit, and electrically connected to the first horizontal conductive line and the second portion of the second horizontal conductive line.

2. The display panel of claim 1, wherein the first horizontal conductive line and the first vertical conductive line are located at different layers from each other.

3. The display panel of claim 2, further comprising an insulating layer between the first horizontal conductive line and the first vertical conductive line,
wherein the first horizontal conductive line is located below the insulating layer, and the first vertical conductive line is located above the insulating layer.

4. The display panel of claim 1, wherein the plurality of pixel circuits further comprises:
a third pixel circuit at the same row as that of the first pixel circuit and the second pixel circuit; and
a fourth pixel circuit at the same row as that of the first pixel circuit and the second pixel circuit, and spaced from the third pixel circuit in the first direction with the transmission area therebetween, and
wherein the display panel further comprises:
a third horizontal conductive line extending in the first direction, and spaced from the transmission area in the second direction;
a fourth horizontal conductive line comprising:
a first portion extending in the first direction, and overlapping with the third pixel circuit; and
a second portion spaced from the first portion of the fourth horizontal conductive line with the transmission area therebetween, extending in the first direction, and overlapping with the fourth pixel circuit;
a third vertical conductive line extending in the second direction, overlapping with the third pixel circuit, and electrically connected to the third horizontal conductive line and the first portion of the fourth horizontal conductive line; and
a fourth vertical conductive line extending in the second direction, overlapping with the fourth pixel circuit, and electrically connected to the third horizontal conductive line and the second portion of the fourth horizontal conductive line.

5. The display panel of claim 4, wherein the third vertical conductive line does not overlap with the first pixel circuit, and the fourth vertical conductive line does not overlap with the second pixel circuit.

6. The display panel of claim 4, wherein the second horizontal conductive line is configured to transmit a bias voltage to the first to fourth pixel circuits, and
wherein the fourth horizontal conductive line is configured to transmit an initialization voltage to the first to fourth pixel circuits.

7. The display panel of claim 4, wherein the third horizontal conductive line and the third vertical conductive line are located at different layers from each other.

8. The display panel of claim 4, wherein the third vertical conductive line is located at a same layer as that of the first vertical conductive line.

9. The display panel of claim 4, wherein the first portion of the second horizontal conductive line overlaps with the first vertical conductive line and the third vertical conductive line, is electrically connected to the first vertical conductive line, and is electrically isolated from the third vertical conductive line, and
wherein the first portion of the fourth horizontal conductive line overlaps with the first vertical conductive line and the third vertical conductive line, is electrically isolated from the first vertical conductive line, and is electrically connected to the third vertical conductive line.

10. The display panel of claim 4, wherein the first vertical conductive line comprises:
a first protrusion overlapping with the first horizontal conductive line; and
a second protrusion overlapping with the third horizontal conductive line,
wherein the first vertical conductive line is electrically connected to the first horizontal conductive line through a contact hole located directly below the first protrusion of the first vertical conductive line, and
wherein a contact hole is not located directly below the second protrusion of the first vertical conductive line.

11. The display panel of claim 10, wherein the third vertical conductive line comprises:
a first protrusion overlapping with the first horizontal conductive line; and
a second protrusion overlapping with the third horizontal conductive line,
wherein the third vertical conductive line is electrically connected to the third horizontal conductive line through a contact hole located directly below the second protrusion of the third vertical conductive line, and
wherein a contact hole is not located directly below the first protrusion of the third vertical conductive line.

12. The display panel of claim 4, wherein the plurality of pixel circuits further comprises a fifth pixel circuit between the first pixel circuit and the third pixel circuit, and
wherein the display panel further comprises a common voltage line extending in the second direction, and overlapping with the fifth pixel circuit.

13. The display panel of claim 12, wherein the common voltage line is located at a same layer as that of the first vertical conductive line and the third vertical conductive line.

14. The display panel of claim 12, wherein the common voltage line overlaps with the first portion of the second horizontal conductive line and the first portion of the fourth horizontal conductive line, and is electrically isolated from the first portion of the second horizontal conductive line and the first portion of the fourth horizontal conductive line.

15. The display panel of claim 12, wherein the common voltage line comprises:
a first protrusion overlapping with the first horizontal conductive line; and
a second protrusion overlapping with the third horizontal conductive line, and
wherein a contact hole is not located directly below the first protrusion and the second protrusion of the common voltage line.

16. The display panel of claim 1, further comprising an auxiliary voltage line surrounding the transmission area, and electrically connecting the first portion and the second portion of the second horizontal conductive line to each other.

17. The display panel of claim 1, wherein the second horizontal conductive line further comprises a third portion extending in the first direction, and connecting the first portion and the second portion of the second horizontal conductive line to each other across the transmission area.

18. The display panel of claim 1, wherein the plurality of pixel circuits further comprises:
a sixth pixel circuit; and
a seventh pixel circuit spaced from the sixth pixel circuit in the second direction with the transmission area therebetween, and
wherein the display panel further comprises a fifth vertical conductive line comprising:
a first portion extending in the second direction, and overlapping with the sixth pixel circuit; and
a second portion spaced from the first portion of the fifth vertical conductive line with the transmission area therebetween, extending in the second direction, and overlapping with the seventh pixel circuit.

19. A display panel comprising:
a substrate comprising:
a transmission area; and
a display area surrounding the transmission area;
an array of a plurality of pixel circuits in the display area in a matrix form along a first direction and a second direction crossing the first direction;
horizontal conductive lines extending in the first direction, and located along the second direction; and
vertical conductive lines extending in the second direction, and located along the first direction,
wherein a first horizontal conductive line configured to transmit a first voltage and a second horizontal conductive line configured to transmit a second voltage from among the horizontal conductive lines overlap with a first row of the array that is spaced from the transmission area in the second direction,
wherein a third horizontal conductive line configured to transmit the first voltage and a fourth horizontal conductive line configured to transmit the second voltage from among the horizontal conductive lines overlap with a second row of the array that overlaps with the transmission area, the third horizontal conductive line and the fourth horizontal conductive line each comprising:
a first portion; and
a second portion spaced from the first portion in the first direction with the transmission area therebetween,
wherein a first vertical conductive line from among the vertical conductive lines overlaps with a first column of the array, is spaced from the transmission area in the first direction, and is electrically connected to the first horizontal conductive line and the first portion of the third horizontal conductive line,
wherein a second vertical conductive line from among the vertical conductive lines overlaps with a second column of the array between the first column and the transmission area, and is electrically connected to the second horizontal conductive line and the first portion of the fourth horizontal conductive line,
wherein a third vertical conductive line from among the vertical conductive lines overlaps with a third column that is spaced from the first column with the transmission area therebetween, and is electrically connected to the first horizontal conductive line and the second portion of the third horizontal conductive line, and
wherein a fourth vertical conductive line from among the vertical conductive lines overlaps with a fourth column that is spaced from the second column with the transmission area therebetween, and is electrically connected to the second horizontal conductive line and the second portion of the fourth horizontal conductive line.

20. An electronic apparatus comprising:
a display panel comprising:
a transmission area; and
a display area surrounding the transmission area; and
a component on a back surface of the display panel, and corresponding to the transmission area,
wherein the display panel further comprises:
a plurality of pixel circuits in the display area, and comprising:
a first pixel circuit; and
a second pixel circuit located in a same row as that of the first pixel circuit, and spaced from the first pixel circuit in a first direction with the transmission area therebetween;
a first horizontal conductive line extending in the first direction, and spaced from the transmission area in a second direction crossing the first direction;
a second horizontal conductive line comprising:
a first portion extending in the first direction, and overlapping with the first pixel circuit; and
a second portion spaced from the first portion with the transmission area therebetween, extending in the first direction, and overlapping with the second pixel circuit;
a first vertical conductive line extending in the second direction, overlapping with the first pixel circuit, and electrically connected to the first horizontal conductive line and the first portion of the second horizontal conductive line; and
a second vertical conductive line extending in the second direction, overlapping with the second pixel circuit, and electrically connected to the first horizontal conductive line and the second portion of the second horizontal conductive line.
